(19) United States
(12) Patent Application Publication
(10) Pub. No.: US 2006/0134464 A1
(43) Pub. Date: Jun. 22, 2006

(54) Organic electroluminescent element

(75) Inventor: Fumito Nariyuki, Kanagawa (JP)

Correspondence Address: BIRCH STEWART KOLASCH & BIRCH, PO BOX 747, FALLS CHURCH, VA, 22040-0747, US

(73) Assignee: FUJI PHOTO FILM CO. LTD

(21) Appl. No.: 11/311,130

(22) Filed: Dec. 20, 2005

(30) Foreign Application Priority Data
Dec. 22, 2004 (JP) 2004-371778

(51) Int. Cl. H01L 51/54; H05B 33/14

(52) U.S. Cl. 428/690; 428/917; 313/504; 313/506; 257/102; 257/103; 257/E51.044; 427/66

(57) ABSTRACT

An organic electroluminescent element having at least one organic compound layer between a pair of electrodes. The at least one organic compound layer includes at least one luminescent layer, and the luminescent layer comprises at least one luminescent dopant and plural host compounds. The main peak in the emission spectrum of a single-layer film comprising only the plural host compounds prepared under the same film-forming conditions under which the luminescent layer is prepared has a wavelength that is at least 15 nm longer than the main peak wavelength of the emission spectrum of each of the plural host compounds.

### CROSS-REFERENCE TO RELATED APPLICATION

This application claims priority under 35 USC 119 from Japanese patent Application No. 2004-371778, the disclosure of which is incorporated by reference herein.

### BACKGROUND OF THE INVENTION

1. Field of the Invention

The present invention relates to an organic electroluminescent element that emits light by converting electric energy to light (hereinafter, also referred to as “organic EL element”, “luminescent element”, or “EL element”).

2. Description of the Related Art

Research and development on various display devices have been conducted actively recently, and among them, organic electroluminescent (EL) elements are attracting attention as a promising display device, because they can emit light of high luminance at lower voltage. It is disclosed, for example in Japanese Patent Application Laid-Open (JP-A) Nos. 2002-313583 and 2002-324673, to use plural compounds as host materials (electron transporting host(s) and hole transporting host(s)) in luminescent layer, so as to reduce power consumption and so as to improve operational durability. However, there is still a need for further improvement in luminous efficiency.

### SUMMARY OF THE INVENTION

After studies, the inventors have found that it is possible to obtain a high luminous efficiency in an element containing host compounds that form an interacting complex in the luminescent layer.

The invention provides an organic electroluminescent element comprising at least one organic compound layer between a pair of electrodes. The at least one organic compound layer includes at least one luminescent layer. The luminescent layer contains at least one luminescent dopant and plural host compounds. The main peak in the emission spectrum of a single-layer film comprising only the plural host compounds prepared under the same film-forming conditions under which the luminescent layer is prepared has a wavelength that is at least 15 nm longer than the main peak wavelength of the emission spectrum of each of the plural host compounds.

At least one of the plural host compounds contained in the luminescent layer may be a compound having an electron affinity Ea of 2.8 eV or more. At least one of the plural host compounds contained in the luminescent layer may be a compound having an ionization potential Ip of 5.4 eV or less. At least one of the plural host compounds contained in the luminescent layer may be a compound represented by the following formula (A-1), (B-1), (C-1), (D-1), or (E-1).

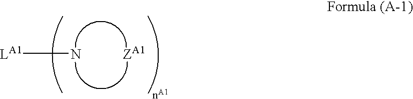

In formula (A-1), L^{A1} represents a connecting group; Z^{A1} represents an atom group necessary for forming a nitrogen-containing heterocyclic ring; n^{A1} represents an integer of 2 or greater; and the compound represented by formula (A-1) has at least three nitrogen atoms in the molecule.

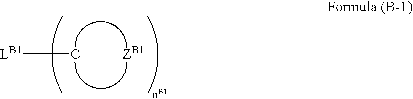

In formula (B-1), L^{B1} represents a connecting group; Z^{B1} represents an atom group necessary for forming an aromatic hydrocarbon ring or an aromatic heterocyclic ring; n^{B1} represents an integer of 2 or greater; and the compound represented by formula (B-1) has at least three nitrogen atoms in the molecule.

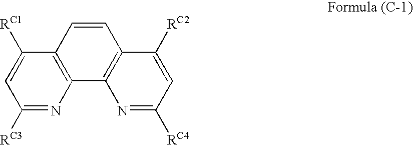

In formula (C-1), R^{C1}, R^{C2}, R^{C3}, and R^{C4} each independently represent a hydrogen atom or a substituent.

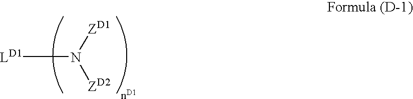

In formula (D-1), L^{D1} represents a connecting group; Z^{D1} and Z^{D2} each independently represent a monovalent atom group; Z^{D1} and Z^{D2} may be bonded to each other to form a nitrogen-containing heterocyclic ring; n^{D1} represents an integer of 2 or greater; and the compound represented by formula (D-1) has at least three nitrogen atoms in the molecule.

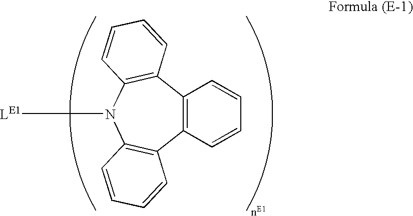

In formula (E-1), L^{E1} represents a connecting group; and n^{E1} represents an integer of 2 or greater.

The light emitted from the luminescent dopant contained in the luminescent layer may be a phosphorescent light.

When the ionization potential of the luminescent dopant is designated as Ip(D) and the minimum ionization potential among those of the plural host compounds is designated as Ip(H)min, ΔIp, which is defined by “ΔIp=Ip(D)−Ip(H)min”, may satisfy the relationship “ΔIp>0 eV”. When the electron affinity of the luminescent dopant is designated as Ea(D) and the maximum electron affinity among those of the plural host compounds is desginated as Ea(H)max, ΔEa, which is defined by “ΔEa=Ea(H)max−Ea(D)”, may satisfy the relationship “ΔEa>0 eV”.

The luminescent layer may be formed by a vapor deposition method in which a mixture of the plural host compounds is used as a deposition source.

The invention further provides a method of producing an organic electroluminescent element. The method comprises forming at least one luminescent layer between a pair of electrodes by a vapor deposition method in which at least one luminescent dopant and a mixture of plural host compounds are used as deposition sources. The main peak in the emission spectrum of a single-layer film comprising only the plural host compounds prepared under the same film-forming conditions under which the luminescent layer is prepared has a wavelength that is at least 15 nm longer than the main peak wavelength of the emission spectrum of each of the plural host compounds.

The organic electroluminescent element of the invention has superior operational durability and luminous efficiency.

### DESCRIPTION OF THE PREFERRED EMBODIMENTS

[Organic Electroluminescent Element]

Hereinafter, the organic electroluminescent element according to the present invention will be described in detail. The organic electroluminescent element according to the invention comprises one or more organic compound layers between a pair of electrodes, wherein the organic compound layers include at least one luminescent layer, the luminescent layer comprises at least one luminescent dopant and plural host compounds, and the main peak in the emission spectrum of a single-layer film comprising only the plural host compounds prepared under the same film-forming conditions under which the luminescent layer is prepared has a wavelength that is at least 15 nm longer than the wavelength of the main peak of the emission spectrum of each of the plural host compounds.

Owing to the above configuration, the organic electroluminescent element according to the invention exhibits superior operational durability and luminous efficiency.

Interaction among the host compounds depends significantly on the donating or accepting properties of the host compounds contained in the luminescent layer. A host compound having higher electron acceptability, or having a greater electron affinity, is more likely to form an interacting complex with one or more other host compounds. In the invention, at least one of the host compounds contained in the luminescent layer preferably has an electron affinity (Ea) of 2.8 eV to 4.0 eV and more preferably, 3.0 eV to 4.0 eV.

Likewise, a host compound having a higher electron donating property, or having a lower ionization potential, is more likely to form an interacting complex with one or more other compounds. In the invention, at least one of the host compounds contained in the luminescent layer preferably has an ionization potential (Ip) of 5.4 eV or less, more preferably 4.0 eV to 5.4 eV, and still more preferably 4.0 eV to 5.1 eV.

In the organic electroluminescent element according to the present invention, emission from the luminescent dopant may be fluorescence or phosphorescence, but phosphorescence, i.e., emission from a multiplet excited state, is preferable.

In addition, in the organic electroluminescent element according to the invention, when the ionization potential of the luminescent dopant is designated as Ip(D) and the minimum ionization potential among those of the plural host compounds is designated as Ip(H)min, ΔIp defined by “ΔIp=Ip(D) Ip(H)min” preferably satisfies the relationship “ΔIp>0 eV.” When the electron affinity of the luminescent dopant is designated as Ea(D) and the maximum electron affinity among those of the plural host compounds is designated as Ea(H)max, ΔEa defined by “ΔEa=Ea(H)max−Ea(D)” preferably satisfies the relationship “ΔEa>0 eV.”

In the invention, energy is transferred to the luminescent dopant via the interacting complex formed by interaction among the plural host compounds contained in the luminescent layer. It is possible to confirm whether or not the interacting complexes is formed through the interaction among the host compounds, by comparing the main peak of the emission spectrum (fluorescence-phosphorescence spectrum) of a single-layer film containing only the plural host compounds prepared under the same film-forming conditions under which the luminescent layer is prepared with the main peak of the emission spectrum (fluorescence-phosphorescence spectrum) of each of the plural host compounds.

In other words, when a longer-wavelength spectral component which is not attributable to the emission spectra of the respective host compounds is observed in the obtained emission spectrum (fluorescence-phosphorescence spectrum), it is considered that the interaction actually occurs.

In the invention, the interaction among the plural host compounds is ascertained when the main peak of the emission spectrum (fluorescence-phosphorescence spectrum) of the above-described single layer has a wavelength that is at least 15 nm longer (but not longer than 150 nm, preferably 20 nm to 120 nm, more preferably, 30 nm to 100 nm) than the main peak of the emission spectrum (fluorescence-phosphorescence spectrum) of any of the plural host compounds.

In the invention, the term “main peak” refers to the peak having the highest emission intensity within the wavelength range of 190 to 800 nm, and the wavelength of the main peak is the wavelength at which the highest emission intensity is obtained.

For example, RF-5300PC manufactured by Shimadzu Corporation may be used to measure the emission spectrum (fluorescence-phosphorescence spectrum). For the measurement, an excitation light having a wavelength which can be absorbed by each host compound is used. The measurement is performed at 25° C. in the atmosphere.

Hereinafter, the ionization potential (Ip), the electron affinity (Ea), and the triplet state level (T₁) mentioned in the invention will be described.

In the present specification, the ionization potential (Ip), the electron affinity (Ea), and the triplet state level (T₁) described below are the ionization potential, electron affintiy and triplet state level of a single-layer film prepared by vacuum-deposition of the test material on a quartz substrate.

The ionization potential (Ip) is a value determined at room temperature in the atmosphere using an ultraviolet photoelectron spectrometer AC-1 (manufactured by Riken Keiki Co., Ltd.). The measurement mechanism of AC−1 is described in Chihaya Adachi et al., “Work Function Data of Organic Thin Films”, (2004, CMC Publishing), the disclosure of which is incorporated herein by reference.

As for the electron affinity (Ea), the band gap is determined from the longest wavelength edge of the absorption spectrum of the single-layer film, and the electron affinity (Ea) is calculated from the band gap and the ionization potential.

The constitution of the organic electroluminescent element of the present invention is described below.

The organic electroluminescent element of the present invention preferably includes a pair of electrodes having one or more organic compound layers including at least one luminescent layer disposed between the pair of electrodes. The organic compound layers preferably further include a carrier transporting layer adjacent to the luminescent layer. The carrier transporting layer is more preferably an electron transporting layer and/or a hole transporting layer.

In view of the nature of the luminescent element, at least one electrode of the paired electrodes is preferably transparent.

As for the layer constitution of the organic compound layers in the present invention, in a preferred embodiment, a hole transporting layer, a luminescent layer and an electron transporting layer are disposed in this order from the anode side. Furthermore, an electron blocking layer and the like may be provided between the hole transporting layer and the luminescent layer, and a hole blocking layer and the like may be provided between the luminescent layer and the electron transporting layer. Also, a hole injecting layer may be provided between the anode and the hole transporting layer, and an electron injecting layer may be provided between the cathode and the electron transporting layer.

In the organic electroluminescent element of the present invention, the organic compound layers preferably include at least a hole injecting layer, a hole transporting layer, a luminescent layer, a hole blocking layer, an electron transporting layer and an electron injecting layer in this order from the anode side.

In the case where a hole blocking layer is provided between the luminescent layer and the electron transporting layer, it is preferable that the organic compound layer adjacent to the luminescent layer on the anode side be a hole transporting layer, and the organic compound layer adjacent to the luminescent layer on the cathode side be a hole blocking layer.

Each layer may be divided into a plurality of secondary layers.

The constituents of the luminescent element of the present invention are described in detail below.

<Organic Compound Layer>

The organic compound layer of the present invention is described below.

The organic electroluminescent element of the present invention includes one or more organic compound layers including at least one luminescent layer. Examples of organic compound layers other than the luminescent layer include, as described above, layers such as a carrier transporting layer (hole transporting layer or electron transporting layer) adjacent to the luminescent layer, a hole blocking layer, a hole injecting layer and an electron injecting layer.

From the viewpoint of decreasing the driving voltage, the organic compound layer preferably has a thickness of 50 nm or less, more preferably 5 to 50 nm, and still more preferably 10 to 40 nm.

The layer adjacent to the luminescent layer on the anode side may be a hole injecting layer, and the layer adjacent to the luminescent layer on the cathode side may be an electron injecting layer or a charge blocking layer. These layers are described in detail below.

(Formation of Organic Compound Layer)

In the organic electroluminescent element of the present invention, each organic compound layer can be appropriately formed by any of a dry film forming method (e.g., vapor-deposition, sputtering), a transfer method, a printing method or the like.

(Luminescent Layer)

The luminescent layer is a layer having a function of, when an electric field is applied, receiving a hole from the anode, hole injecting layer or hole transporting layer, and receiving an electron from the cathode, electron injecting layer or electron transporting layer, thereby providing a site for the recombination of a hole and an electron to emit light.

The luminescent layer for use in the present invention contains at least one luminescent dopant and a plurality of host compounds. The luminescent layer is not particularly limited as long as the above interaction occurs between the plurality of host compounds.

The luminescent layer may be a single layer or two or more layers. Each of the two or more layers may emit light with different emission color. When the luminescent element includes a plurality of luminescent layers, each of the luminescent layers preferably contains at least one luminescent dopant and a plurality of host compounds.

The combination of the luminescent dopant and the plural host materials may be a combination of a fluorescence luminescent dopant and plural host compounds that generates emission from a singlet exciton (fluorescence) or a combination of a phosphorescent luminescent dopant and plural host compounds that generates emission from a triplet exciton (phosphorescence), but the combination of a phosphorescent luminescent dopant and plural host compounds is preferable from the viewpoint of luminous efficiency.

The luminescent layer according to the invention may contain two or more luminescent dopants so as to improve the color purity.

The luminescent dopant and the plural host compounds according to the invention will be described in more detail below.

-Host Compound-

As described above, the luminescent layer comprises plural host compounds. In the invention, the interaction between the plural host compounds is important; the interaction can be confirmed when the main peak of the emission spectrum of a single-layer film comprising only the plural host compounds prepared under the same film-forming conditions under which the luminescent layer is prepared has a wavelength that is longer by at least 15 nm than the main peak of the emission spectrum of each of the plural host compounds.

At least one of the plural host materials contained in the luminescent layer preferably has an electron affinity Ea of 2.8 eV or more.

In addition, at least one of the plural host materials contained in the luminescent layer preferably has an ionization potential Ip of 5.4 eV or less Further, the plural host compounds and the luminescent dopant preferably satisfy the following relationship:
ΔIp(=Ip(D)−Ip(H)min)>0 eV, and ΔEa(=Ea(H)max−Ea(D))>0 eV. (1)

Under the condition of the relationship (1), more preferable relationship is the following relationship (2):
1.2 eV>ΔIp>0.2 eV, and/or 1.2 eV>ΔEa>0.2 eV (2)

In the invention, when one luminescent dopant and plural host compounds are used, the luminescent dopant is preferably such that: IP(D) is greater than Ip(H)min, i.e., Ip(D)>Ip(H)min; and Ea(D) is smaller than Ea(H)max, i.e., Ea(H)max>Ea(D), wherein the host compound giving Ip(H)min and the host compound giving Ea(H)max are different.

An example of the host compound corresponding to the Ip(H)min is a hole transporting host, and an example of the host compound corresponding to the Ea(H)max is an electron transporting host.

When plural luminescent dopants are used, the Ip(D) is the ionization potential of a dopant having the smallest Ip, and the Ea(D) is the electron affinity of a dopant having the greatest Ea.

In an embodiment, a hole transporting host compound (hole transporting host) superior in hole transporting efficiency and an electron transporting host compound (electron transporting host) superior in electron-transporting efficiency are used as the plural host compounds. In a preferable embodiment, the combination of a hole transporting host having an ionization potential Ip of 5.4 eV or less and an electron transporting host having an electron affinity Ea of 2.8 eV or more is used as the plural host compounds.

The plural host compounds are more preferably a combination of an electron transporting host selected from compounds represented by formulae (A-1), (B-1), and (C-1) and a hole transporting host selected from compounds represented by formulae (D-1) and (E-1).

-Hole Transporting Host-

The hole transporting host for use in the luminescent layer according to the invention is not particularly limited as long as it interacts with other host compounds contained in the luminescent layer.

The hole transporting host is preferably a compound having an ionization potential Ip of 5.4 eV or less, and is preferably a hole transporting material that satisfies the relationships of:
ΔIp(=Ip(D)−Ip(H)min)>0 eV, and ΔEa(=Ea(H)max−Ea(D))>0 eV. (1)

Typical examples of the hole transporting host include the following materials: pyrrole, carbazole, triazole, oxazole, oxadiazole, imidazole, polyarylalkanes, pyrazoline, pyrazolone, phenylenediamine, arylamine, amino-substituted chalcones, styryl anthracene, fluorenone, hydrazone, stilbene, silazane, aromatic tertiary amine compounds, styrylamine compounds, aromatic dimethylydene compounds, porphyrin compounds, polysilane compounds, poly(N-vinylcarbazole), aniline copolymers, thiophene oligomers, conductive polymer oligomers such as polythiophene, organic silanes, carbon films, and derivatives thereof.

The hole transporting host preferably satisfies the relationship (2), and examples thereof include carbazole derivatives, aromatic tertiary amine compounds, and thiophene derivatives. Compounds each having plural carbazole skeletons and/or aromatic tertiary amine skeletons are more preferable.

The hole transporting host is preferably a compound represented by formula (D-1) or (E-1).

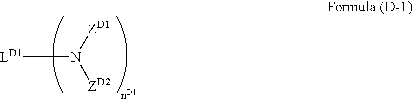

In formula (D-1), L^{D1} represents a connecting group; Z^{D1} and Z^{D2} each independently represent a monovalent atom group; Z^{D1} and Z^{D2} may be bonded to each other to form a nitrogen-containing heterocyclic ring; n^{D1} represents an integer of 2 or greater; and the compound represented by formula (D-1) has at least three nitrogen atoms in the molecule.

In formula (D-1), L^{D1} represents a connecting group. The connecting group represented by L^{D1} is preferably a single bond or a connecting group containing carbon, silicon, nitrogen, phosphorus, sulfur, oxygen, boron, germanium, or the like. L^{D1} is more preferably a single bond, a carbon, silicon, boron, oxygen, sulfur, or germanium atom, an aromatic hydrocarbon ring, or an aromatic heterocyclic ring; more preferably a carbon or silicon atom, an aromatic hydrocarbon or heterocyclic ring; still more preferably a bivalent or higher-valent aromatic hydrocarbon ring, a bivalent or higher-valent aromatic heterocyclic ring, or a carbon atom; more preferably a bivalent or higher-valent aromatic hydrocarbon or heterocyclic ring; and particularly preferably 1,3,5-benzenetriyl, 1,2,5,6-benzenetetrayl, 1,2,3,4,5,6-benzenehexayl, 2,2′-dimethyl-4,4′-biphenylene, 2,4,6-pyridinetriyl, 2,4,6-triazinetriyl.

Typical examples of the connecting group represented by L^{D1} include, but are not limited to, the followings:

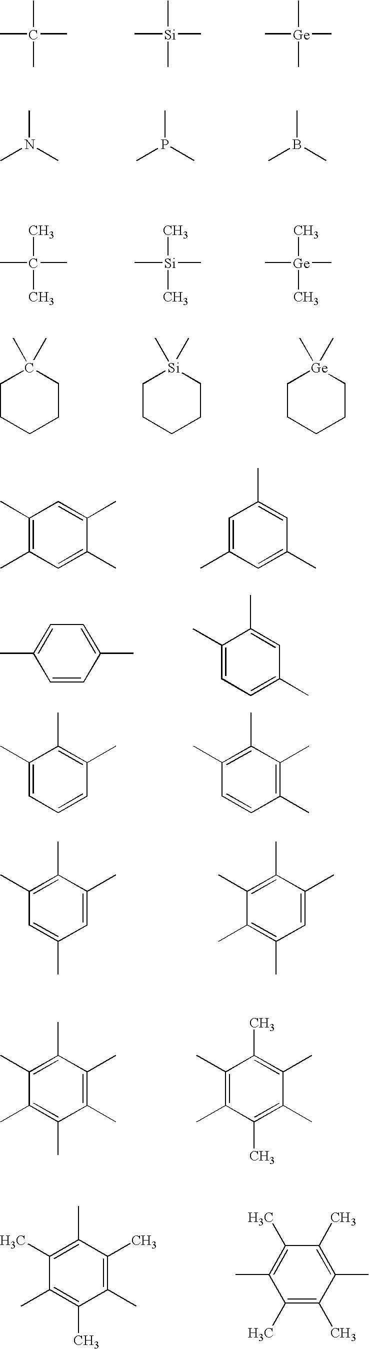

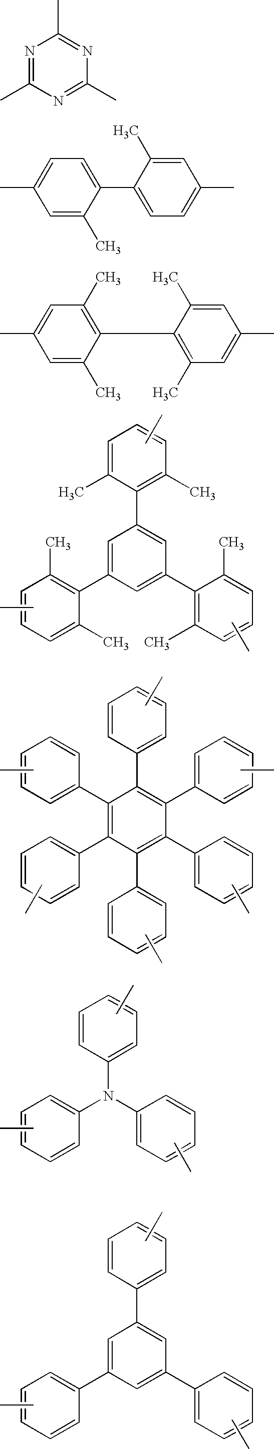

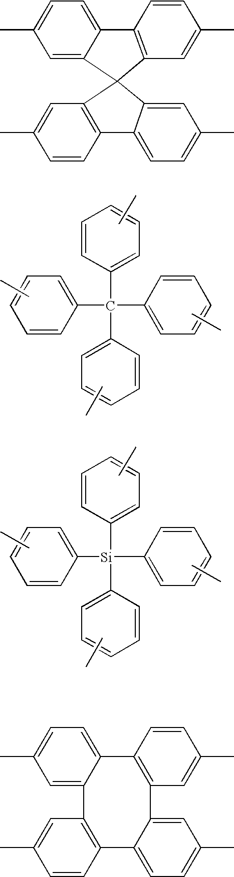

L^{D1} may have a substituent, and examples of the substituent include alkyl groups (preferably, those having 1 to 30 carbon atoms, more preferably 1 to 20 carbon atoms, and particularly preferably 1 to 10 carbon atoms, such as methyl, ethyl, iso-propyl, tert-butyl, n-octyl, n-decyl, n-hexadecyl, cyclopropyl, cyclopentyl, or cyclohexyl).

In formula (D-1), n^{D1} represents an integer of 2 or greater, preferably 2 to 8, and more preferably 2 to 6.

Z^{D1} and Z^{D2} each independently represent a monovalent atom group and is preferably an aromatic hydrocarbon ring group which may have a substituent. Z^{D1} and Z^{D2} may be bonded to each other to form a nitrogen-containing heterocyclic ring. The structures of Z^{D1} and Z^{D2} are each preferably a structure represented by the following formula (D-2).

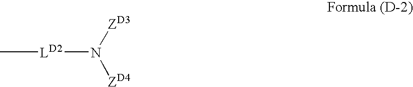

In formula (D-2), L^{D2} represents a connecting group; Z^{D3} and Z^{D4} each independently represent a monovalent atom group; and Z^{D3} and Z^{D4} may be bonded to each other to form a nitrogen-containing heterocyclic ring.

In formula (D-2), L^{D2} preferably has a structure similar to L^{D1} in formula (D-1). However, L^{D1} and L^{D2} may not necessarily be the same as each other.

In formula (D-2), Z^{D3} and Z^{D4} each independently represent a monovalent atom group, and explanations on Z^{D3} and Z^{D4} are the same as the above explanations on Z^{D1} and Z^{D2} in formula (D-1).

Examples of the aromatic hydrocarbon ring groups represented by Z^{D1} to Z^{D4} in formula (D-1) and (D-2) include five- to six-membered monocycles and fused rings each containing two to four five- to six-membered rings, such as phenyl, naphthyl, anthranyl, and naphthacenyl group. The aromatic hydrocarbon ring group may have one or more substituents selected from alkyl groups such as methyl and ethyl, halogen atoms such as fluorine, and α-haloalkyl groups such as trifluoromethyl.

When Z^{D1} and Z^{D2} form a nitrogen-containing heterocyclic ring, the nitrogen-containing heterocyclic ring is preferably a carbazole group. When Z^{D3} and Z^{D4} form a nitrogen-containing heterocyclic ring, the nitrogen-containing heterocyclic ring is preferably a carbazole group. The carbazole group may have a substituent whose examples include an alkyl group such as methyl or ethyl, a halogen atom such as fluorine, and an α-haloalkyl group such as trifluoromethyl.

Typical examples of the compound represented by formula (D-1) include, but are not limited to, the following compounds:

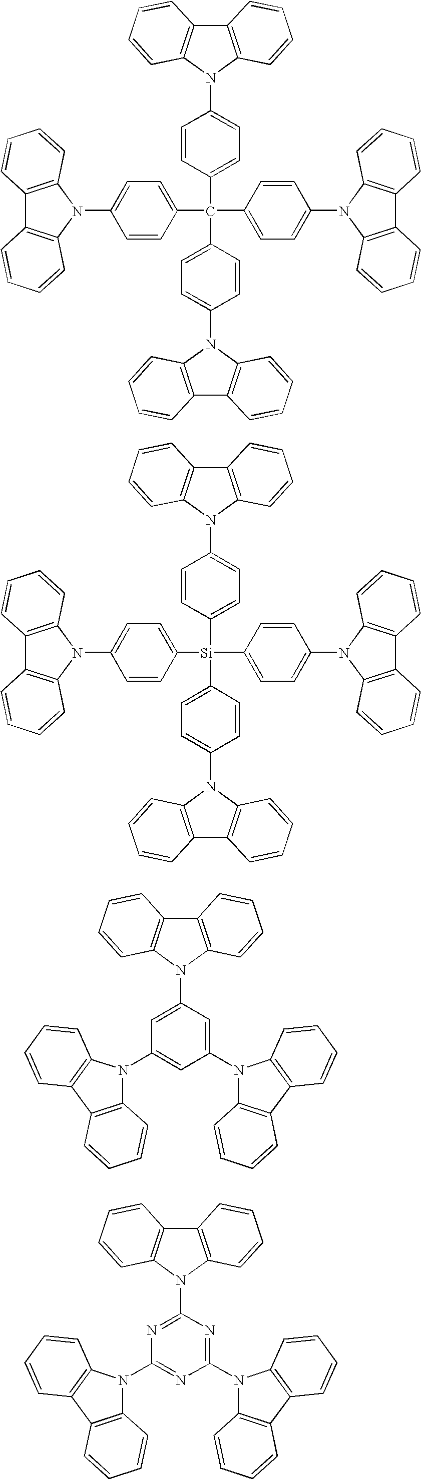

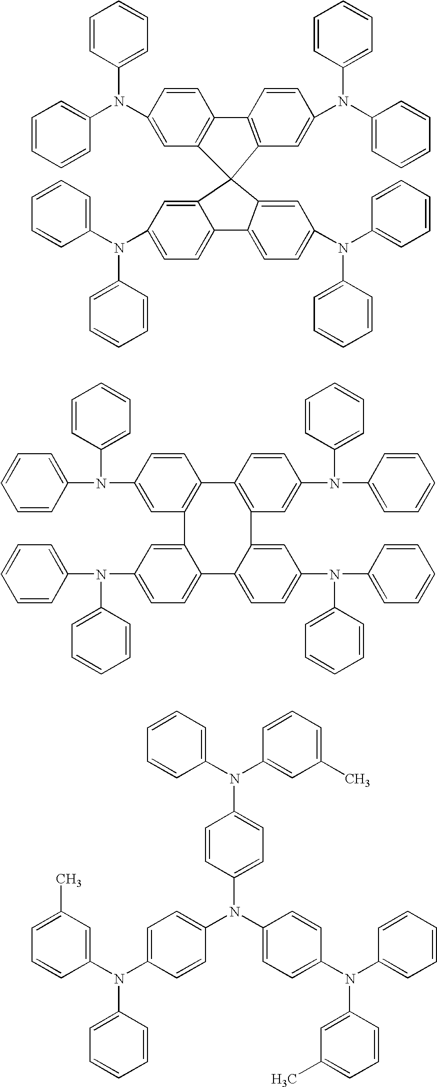

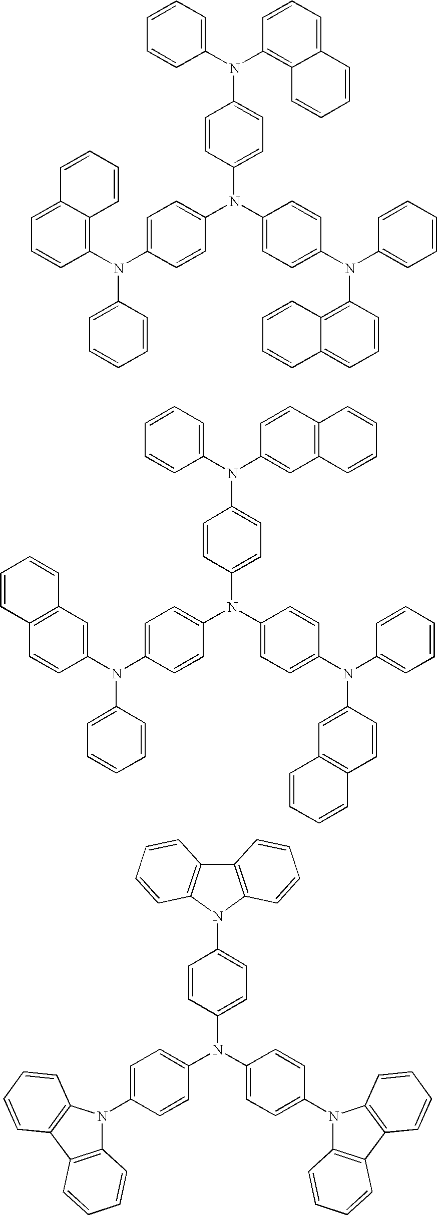

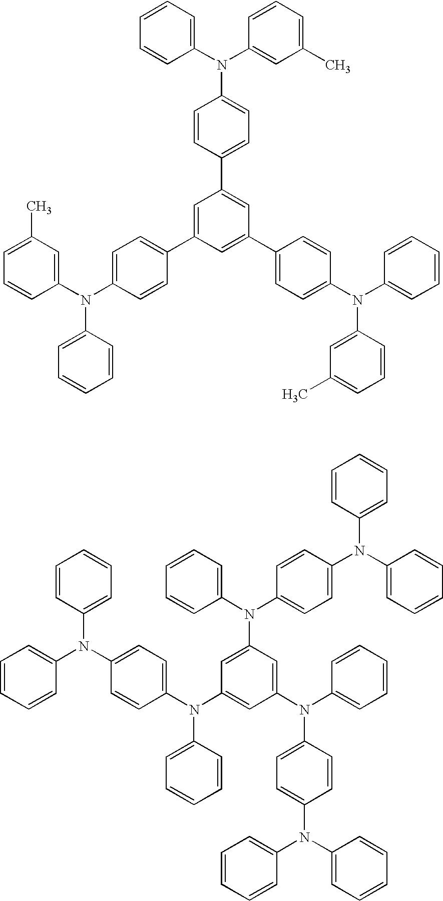

The compound represented by formula (E-1) will be described below.
Formula (E-1)

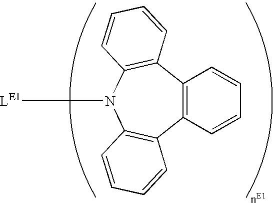

In formula (E-1), L^{E1} represents a connecting group; and n^{E1} represents an integer of 2 or greater.

The connecting group represented by L^{E1} in formula (E-1) may be selected from the connecting groups mentioned above as examples of L^{D1} in formula (D-1).

Typical examples of the compounds represented by formula (E-1) include, but are not limited to, the following compounds: 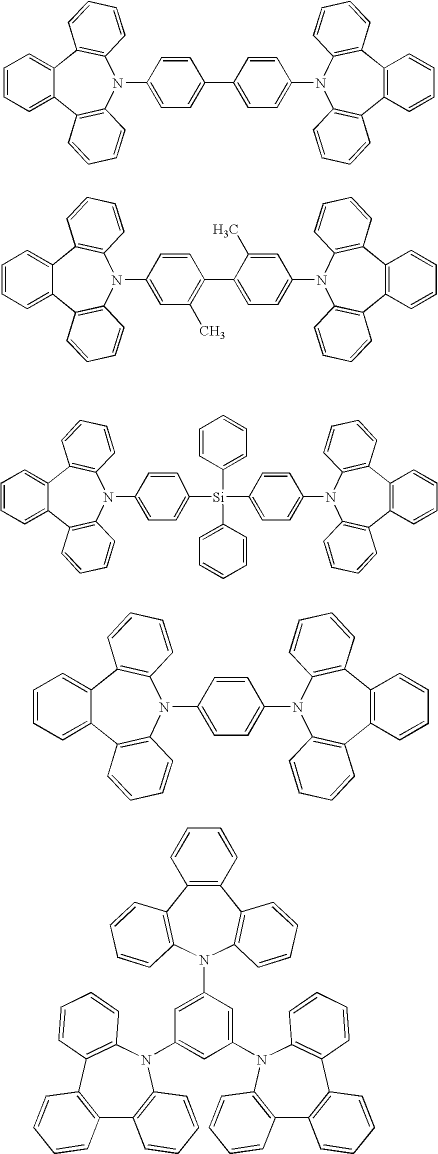 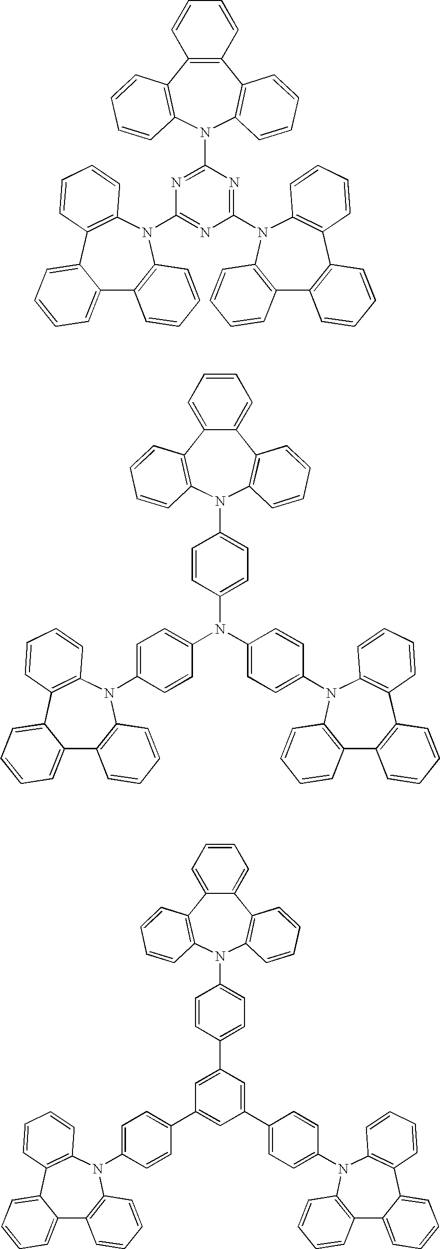
-Electron Transporting Host-

The electron transporting host for use in the luminescent layer according to the invention is not particularly limited as long as it interacts with other host compounds contained in the luminescent layer. The electron transporting host is preferably a compound having an electron affinity Ea of 2.8 eV or more, and is preferably an electron transporting material that satisfies the above-described relationships, (1) ΔIp (=Ip(D)−Ip(H)min)>0 eV, and ΔEa (=Ea(H)max−Ea(D))>0 eV.

Specific examples thereof include: pyridine, pyrimidine, triazine, imidazole, triazole, oxazole, oxadiazole, fluorenone, anthraquinodimethane, anthrone, diphenylquinone, thiopyranedioxide, carbodiimide, fluorenylidenemethane, distyrylpyrazine, fluorine-substituted aromatic compounds, heterocyclic tetracarboxylic acid anhydrides such as naphthalene and perylene having tetracarboxylic acid anhydrides, phthalocyanine, and derivatives thereof (which may be fused with another ring to form a condensed ring); metal complexes of 8-quinolinol derivatives, metal phthalocyanines, and various metal complexes such as metal complexes having benzoxazole or benzothiazole as a ligand.

Among these electron transporting hosts, metal complexes, azole derivatives (e.g., benzimidazole derivative, imidazopyridine derivative) and azine derivatives (e.g., pyridine derivative, pyrimidine derivative, triazine derivative) are preferred, and in view of durability, metal complex compounds are more preferred in the present invention. The metal complex compounds are each preferably a metal complex in which a ligand containing at least one nitrogen atom, oxygen atom or sulfur atom is coordinated to the metal. The metal ion in the metal complex is not particularly limited but is preferably a beryllium ion, a magnesium ion, an aluminum ion, a gallium ion, a zinc ion, an indium ion or a tin ion, more preferably a beryllium ion, an aluminum ion, a gallium ion or a zinc ion, still more preferably an aluminum ion or a zinc ion.

As for the ligand contained in the metal complex, various ligands are known, and examples thereof include the ligands described in H. Yersin, Photochemistry and Photophysics of Coordination Compounds, Springer-Verlag (1987), and Akio Yamamoto, Yuki Kinzoku Kagaku-Kiso to Oyo-(Organic Metal Chemistry-Basics and Applications-), Shokabo (1982), the disclosures of which are incorporated by reference herein.

The electron transporting host satisfying the relationship (2) (1.2 eV>ΔIp>0.2 eV, and/or 1.2 eV>ΔEa>0.2 eV) is preferably a compound represented by formula (A-1), (B-1), or (C-1).

The compound represented by formula (A-1) will be described below.

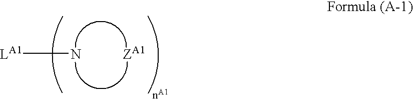

In formula (A-1), L^{A1} represents a connecting group; n^{A1} represents an integer of 2 or greater; Z^{A1} represents an atom group necessary for forming a nitrogen-containing heterocyclic ring; and the compound represented by formula (A-1) has at least three nitrogen atoms in the molecule.

In formula (A-1), L^{A1} represents a connecting group. The connecting group represented by L^{A1} is preferably a single bond or a connecting group containing one or more atoms selected from carbon, silicon, nitrogen, phosphorus, sulfur, oxygen, boron, germanium, and the like. L^{A1} is more preferably a single bond, a carbon, silicon, boron, oxygen, sulfur or germanium atom, an aromatic hydrocarbon ring, or an aromatic heterocyclic ring, still more preferably a carbon or silicon atom, an aromatic hydrocarbon ring, or an aromatic heterocyclic ring; further more preferably a bivalent or higher-valent aromatic hydrocarbon ring, a bivalent or higher-valent aromatic heterocyclic ring, or a carbon atom, still further preferably a bivalent or higher-valent aromatic hydrocarbon ring or a bivalent or higher-valent aromatic heterocyclic ring, and especially preferably a 1,3,5-benzenetriyl, 1,2,5,6-benzenetetrayl, 1,2,3,4,5,6-benzenehexayl, 2,2′-dimethyl-4,4′-biphenylene, 2,4,6-pyridinetriyl, 2,3,4,5,6-pyridinepentayl, 2,4,6-pyrimidinetriyl, 2,4,6-triazinetriyl, or 2,3,4,5-thiophenetetrayl group.

Typical examples of the connecting group represented by L^{A1} include, but are not limited to, the followings:

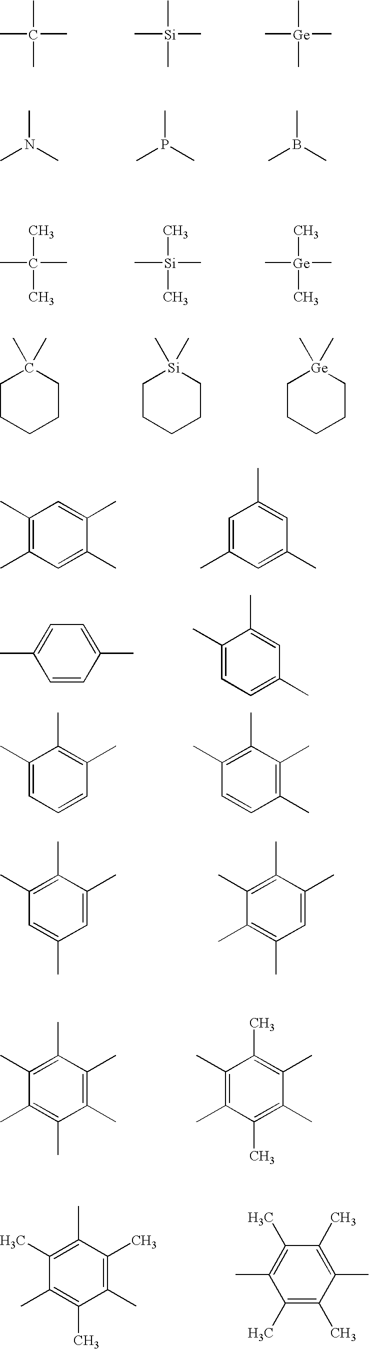

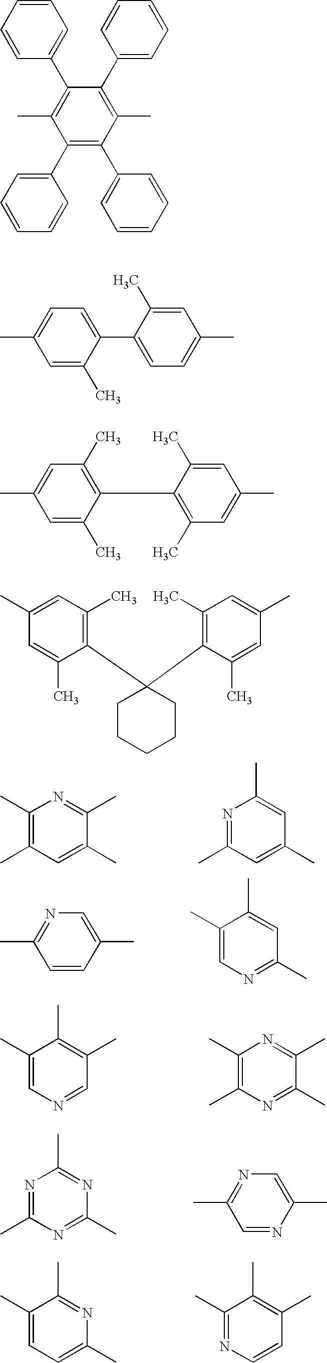

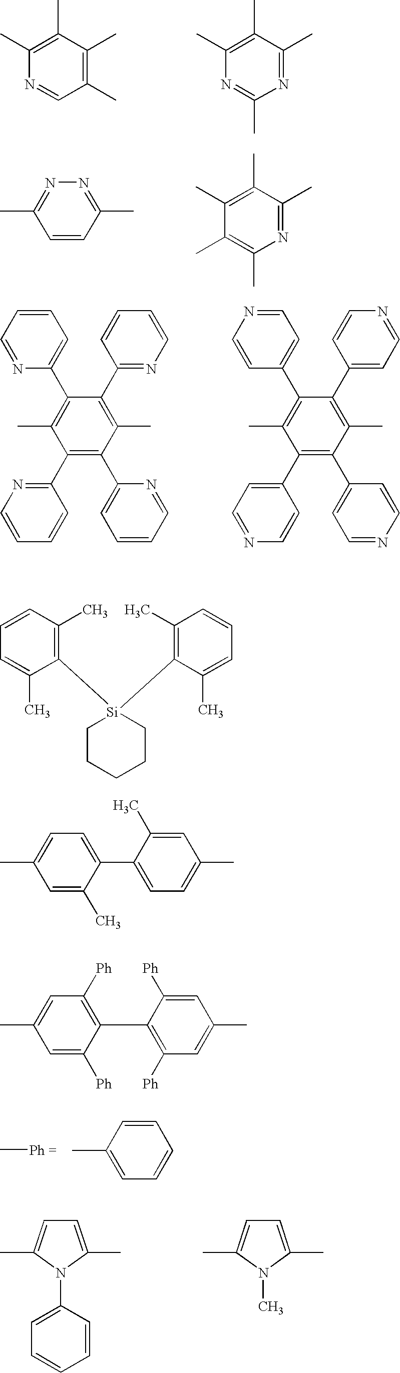

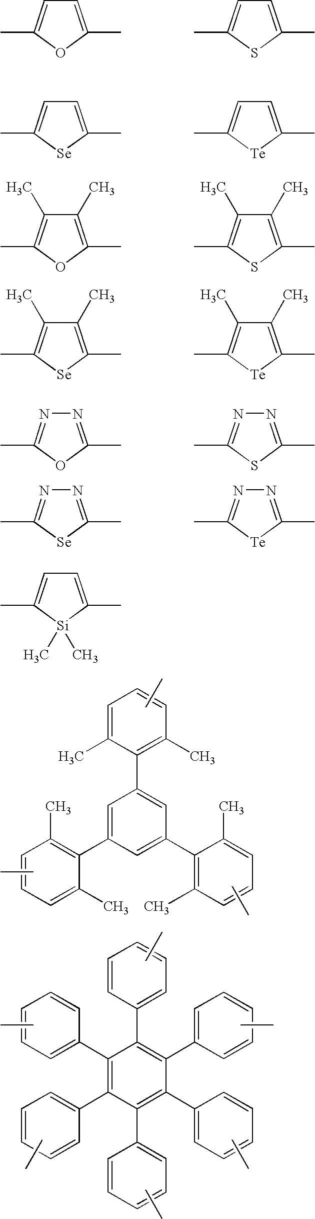

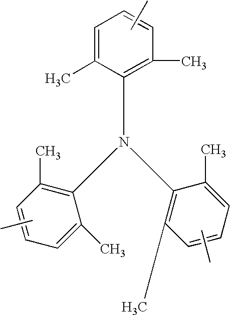

L^{A1} may have a substituent, and examples of the substituent include alkyl groups (preferably, those having 1 to 30 carbon atoms, more preferably 1 to 20 carbon atoms, and particularly preferably 1 to 10 carbon atoms, such as methyl, ethyl, iso-propyl, tert-butyl, n-octyl, n-decyl, n-hexadecyl, cyclopropyl, cyclopentyl, and cyclohexyl), alkenyl groups (preferably, those having 2 to 30 carbon atoms, more preferably 2 to 20 carbon atoms, and particularly preferably 2 to 10 carbon atoms, such as vinyl, allyl, 2-butenyl, and 3-pentenyl), alkynyl groups (preferably, those having 2 to 30 carbon atoms, more preferably 2 to 20 carbon atoms, and particularly preferably 2 to 10 carbon atoms, such as propargyl and 3-pentynyl), aryl groups (preferably, those having 6 to 30 carbon atoms, more preferably 6 to 20 carbon atoms, and particularly preferably 6 to 12 carbon atoms, such as phenyl, p-methylphenyl, naphthyl, and anthranyl), amino groups (preferably, those having 0 to 30 carbon atoms, more preferably 0 to 20 carbon atoms, and particularly preferably 0 to 10 carbon atoms, such as amino, methylamino, dimethylamino, diethylamino, dibenzylamino, diphenylamino, and ditolylamino), alkoxy groups (preferably, those having 1 to 30 carbon atoms, more preferably 1 to 20 carbon atoms, and particularly preferably 1 to 10 carbon atoms, such as methoxy, ethoxy, butoxy, and 2-ethylhexyloxy), aryloxy groups (preferably, those having 6 to 30 carbon atoms, more preferably 6 to 20 carbon atoms, and particularly preferably 6 to 12 carbon atoms, such as phenyloxy, 1-naphthyloxy, and 2-naphthyloxy), heterocyclic oxy groups (preferably, those having 1 to 30 carbon atoms, more preferably 1 to 20 carbon atoms, and particularly preferably 1 to 12 carbon atoms, such as pyridyloxy, pyrazyloxy, pyrimidyloxy, and quinolyloxy), acyl groups (preferably, those having 1 to 30 carbon atoms, more preferably 1 to 20 carbon atoms, and particularly preferably 1 to 12 carbon atoms, such as acetyl, benzoyl, formyl, and pivaloyl), alkoxycarbonyl groups (preferably, those having 2 to 30 carbon atoms, more preferably 2 to 20 carbon atoms, and particularly preferably 2 to 12 carbon atoms, such as methoxycarbonyl and ethoxycarbonyl), aryloxycarbonyl groups (preferably, those having 7 to 30 carbon atoms, more preferably 7 to 20 carbon atoms, and particularly preferably 7 to 12 carbon atoms, such as phenyloxycarbonyl), acyloxy groups (preferably, those having 2 to 30 carbon atoms, more preferably 2 to 20 carbon atoms, and particularly preferably 2 to 10 carbon atoms, such as acetoxy and benzoyloxy), acylamino groups (preferably, those having 2 to 30 carbon atoms, more preferably 2 to 20 carbon atoms, and particularly preferably 2 to 10 carbon atoms, such as acetylamino and benzoylamino), alkoxycarbonylamino groups (preferably, those having 2 to 30 carbon atoms, more preferably 2 to 20 carbon atoms, and particularly preferably 2 to 12 carbon atoms, such as methoxycarbonylamino), aryloxycarbonylamino groups (preferably, those having 7 to 30 carbon atoms, more preferably 7 to 20 carbon atoms, and particularly preferably 7 to 12 carbon atoms, such as phenyloxycarbonylamino), sulfonylamino groups (preferably, those having 1 to 30 carbon atoms, more preferably 1 to 20 carbon atoms, and particularly preferably 1 to 12 carbon atoms, such as methanesulfonylamino and benzenesulfonylamino), sulfamoyl groups (preferably, those having 0 to 30 carbon atoms, more preferably 0 to 20 carbon atoms, and particularly preferably 0 to 12 carbon atoms, such as sulfamoyl, methylsulfamoyl, dimethylsulfamoyl, and phenylsulfamoyl), carbamoyl groups (preferably, those having 1 to 30 carbon atoms, more preferably 1 to 20 carbon atoms, and particularly preferably 1 to 12 carbon atoms, such as carbamoyl, methylcarbamoyl, diethylcarbamoyl, and phenylcarbamoyl), alkylthio groups (preferably, those having 1 to 30 carbon atoms, more preferably 1 to 20 carbon atoms, and particularly preferably 1 to 12 carbon atoms, such as methylthio and ethylthio), arylthio groups (preferably, those having 6 to 30 carbon atoms, more preferably 6 to 20 carbon atoms, and particularly preferably 6 to 12 carbon atoms, such as phenylthio), heterocyclic ring thio groups (preferably, those having 1 to 30 carbon atoms, more preferably 1 to 20 carbon atoms, and particularly preferably 1 to 12 carbon atoms, such as pyridylthio, 2-benzimidazolylthio, 2-benzoxazolylthio, and 2-benzothiazolylthio), sulfonyl groups (preferably, those having 1 to 30 carbon atoms, more preferably 1 to 20 carbon atoms, and particularly preferably 1 to 12 carbon atoms, such as mesyl and tosyl), sulfinyl groups (preferably, those having 1 to 30 carbon atoms, more preferably 1 to 20 carbon atoms, and particularly preferably 1 to 12 carbon atoms, such as methanesulfinyl and benzenesulfinyl), ureido groups (preferably, those having 1 to 30 carbon atoms, more preferably 1 to 20 carbon atoms, and particularly preferably 1 to 12 carbon atoms, such as ureido, methylureido, and phenylureido), phosphoric amido groups (preferably, those having 1 to 30 carbon atoms, more preferably 1 to 20 carbon atoms, and particularly preferably 1 to 12 carbon atoms, such as diethylphosphoric amido, and phenylphosphoric amido), a hydroxy group, a mercapto group, halogen atoms (e.g., fluorine, chlorine, bromine, and iodine), a cyano group, a sulfo group, a carboxyl group, a nitro group, a hydroxamic acid group, sulfino groups, hydrazino groups, imino groups, heterocyclic ring groups (preferably, those having 1 to 30 carbon atoms, more preferably 1 to 12 carbon atoms, in which one or more heteroatoms may be selected from nitrogen, oxygen, and sulfur, such as imidazolyl, pyridyl, quinolyl, furyl, thienyl, piperidyl, morpholino, benzoxazolyl, benzimidazolyl, benzothiazolyl, carbazolyl, and azepinyl), silyl groups (preferably, those having 3 to 40 carbon atoms, more preferably 3 to 30 carbon atoms, and particularly preferably 3 to 24 carbon atoms, such as trimethylsilyl and triphenylsilyl), and silyloxy groups (preferably, those having 3 to 40 carbon atoms, more preferably 3 to 30 carbon atoms, and particularly preferably 3 to 24 carbon atoms, such as trimethylsilyloxy and triphenylsilyloxy). These substituents themselves may have a substituent, which is preferably a halogen atom or an alkyl, aryl, heterocyclic, or silyl group; more preferably an alkyl, aryl, or heterocyclic group or a halogen atom; and still more preferably an alkyl, aryl, or aromatic heterocyclic group or a fluorine atom.

In formula (A-1), Z^{A1} represents an atom group necessary for forming a nitrogen-containing heterocyclic ring, and the nitrogen-containing heterocyclic ring containing Z^{A1} may be a monocycle or a fused ring containing two or more rings fused to each other. The nitrogen-containing heterocyclic ring containing Z^{A1} is preferably a five-membered to eight-membered nitrogen-containing heterocyclic ring, more preferably a five-membered to seven-membered nitrogen-containing heterocyclic ring, still more preferably five-membered or six-membered nitrogen-containing aromatic heterocyclic ring, and particularly preferably a five-membered aromatic heterocyclic ring. The plural nitrogen-containing heterocyclic rings which each contain Z^{A1} and which are connected to L^{A1} may be the same as or different from each other.

Typical examples of the nitrogen-containing heterocyclic ring containing Z^{A1} include pyrrole, indole, oxazole, oxadiazole, thiazole, thiazaindole, azaindole, carbazole, carboline (norharmane), imidazole, benzimidazole, imidazopyridine, purine, pyrazole, indazole, azaindazole, triazole, tetrazole, azepine, iminostilbene (dibenzazepine), tribenzazepine, phenothiazine, and phenoxazine rings. Oxadiazole, triazole, imidazole, benzimidazole, and imidazopyridine rings are preferable and benzimidazole and imidazopyridine rings are more preferable.

If possible, Z^{A1} may fuse with one or more other rings to form a fused ring. Z^{A1} may have a substituent. The substituent may be selected from the substituents described above as examples of the substituent on L^{A1} in formula (A-1), and a preferable range of the substituent is also the same as in the case of the substituent on L^{A1} in formula (A-1).

In formula (A-1), n^{A1} represents an integer of 2 or greater, preferably 2 to 8, and more preferably 2 to 6.

Typical examples of the compound represented by formula (A-1) include the following compounds:

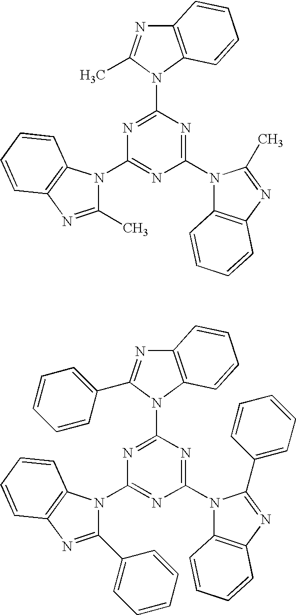

The compounds represented by formula (B-1) will be described below.

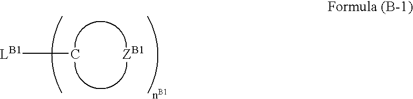

In formula (B-1), L represents a connecting group; Z^{B1} represents an atom group necessary for forming an aromatic hydrocarbon ring or an aromatic heterocyclic ring; n^{B1} represents an integer of 2 or greater; and the compound represented by formula (B-1) has at least three nitrogen atoms in the molecule.

In formula (B-1), L^{B1} represents a connecting group. Examples of the connecting group represented by L^{B1} include the connecting groups described above as examples of L^{A1} in formula (A-1). L^{B1} is preferably a single bond, a bivalent or higher-valent aromatic hydrocarbon ring, a bivalent or higher-valent aromatic heterocyclic ring, or a carbon, nitrogen, or silicon atom; more preferably a bivalent or higher-valent aromatic hydrocarbon ring or a bivalent or higher-valent aromatic heterocyclic ring, still more preferably 1,3,5-benzenetriyl, 1,2,5,6-benzenetetrayl, 1,2,3,4,5,6-benzenehexayl, 2,2′-dimethyl-4,4′-biphenylene, 2,4,6-pyridinetriyl, 2,3,4,5,6-pyridinepentayl, 2,4,6-pyrimidinetriyl, 2,4,6-triazinetriyl or 2,3,4,5-thiophenetetrayl group, or a carbon, nitrogen, or silicon atom.

L^{B1} may have a substituent, and the substituent may be selected from the substituents described above as examples of the substituent on L^{A1} in formula (A-1), and a preferable range of the substituent is also the same as in the case of the substituent on L^{A1} in formula (A-1).

Z^{B1} represents an atom group necessary for forming an aromatic hydrocarbon ring or an aromatic heterocyclic ring, and the aromatic hydrocarbon ring or aromatic heterocyclic ring containing Z^{B1} may be a monocycle or a fused ring containing two or more rings fused with each other. The plural rings which each contain Z^{B1} and which are connected to L^{B1} may be the same as or different from each other.

The aromatic hydrocarbon ring containing Z^{B1} is an aromatic hydrocarbon ring preferably having 6 to 30 carbon atoms, more preferably having 6 to 20 carbon atoms, and particularly preferably having 6 to 12 carbons, and examples thereof include benzene, naphthalene, anthracene, phenanthrene, pyrene, and triphenylene rings. Benzene, naphthalene, phenanthrene, and triphenylene rings are preferable.

The aromatic heterocyclic ring containing Z^{B1} is a monocyclic heterocycle or a fused heterocycle containing two or more rings fused with each other, and is preferably an aromatic heterocyclic ring having 1 to 20 carbon atoms, more preferably having 2 to 12 carbon atoms, and still more preferably having 2 to 10 carbons. The heterocyclic ring is preferably an aromatic heterocyclic ring containing at least one atom selected from nitrogen, oxygen, and sulfur atoms. Typical examples of the heterocyclic ring containing Z^{B1} include pyridine, quinoline, isoquinoline, acridine, phenanthridine, pteridine, pyrazine, quinoxaline, pyrimidine, quinazoline, pyridazine, cinnoline, phthalazine, triazine, oxazole, benzoxazole, thiazole, benzothiazole, imidazole, benzimidazole, pyrazole, indazole, isooxazole, benzisoxazole, isothiazole, benzisothiazole, oxadiazole, thiadiazole, triazole, tetrazole, furan, benzofuran, thiophene, benzothiophene, pyrrole, indole, imidazopyridine, carbazole, and phenanthroline rings. The heterocyclic ring is preferably a pyridine, quinoline, isoquinoline, acridine, phenanthridine, pyrazine, quinoxaline, pyrimidine, quinazoline, pyridazine, phthalazine, triazine, imidazole, benzimidazole, pyrazole, indazole, oxadiazole, triazole, imidazopyridine, carbazole, or phenanthroline ring, more preferably a pyridine, quinoline, isoquinoline, pyrazine, quinoxaline, pyrimidine, quinazoline, pyridazine, phthalazine, triazine, imidazole, benzimidazole, oxadiazole, triazole, imidazopyridine, or phenanthroline ring, still more preferably a benzimidazole, oxadiazole, triazole, imidazopyridine, or phenanthroline ring, and particularly preferably a benzimidazole or imidazopyridine ring.

The aromatic hydrocarbon ring or aromatic heterocyclic ring containing Z^{B1} may be fused with one or more other rings to form a fused ring, and may have a substituent. The substituent may be selected from the substituents described above as examples of the substituent on L^{A1} in formula (A-1), and a preferable range of the substituent is also the same as in the case of the substituent on L^{A1} in formula (A-1).

Typical examples of the compound represented by formula (B-1) include the following compounds.

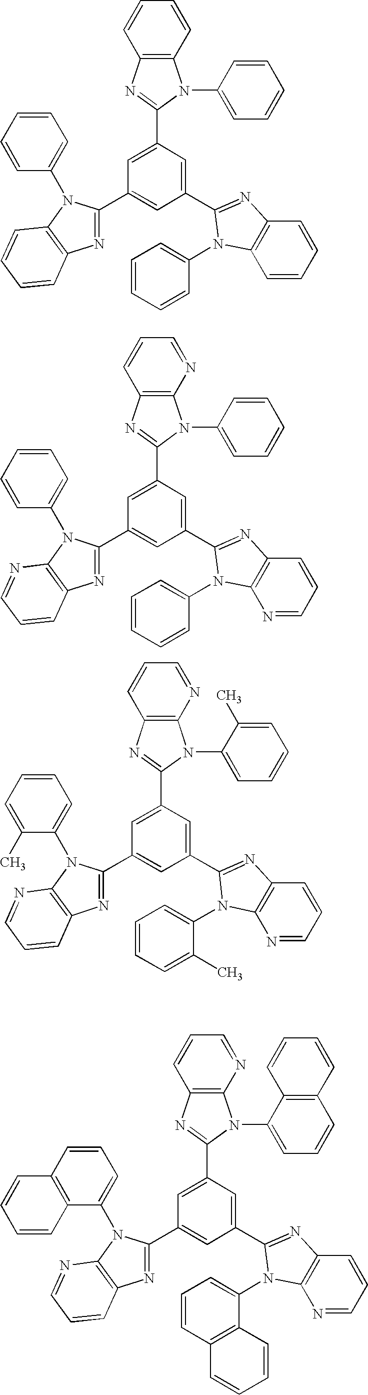

In formula (B-1), n^{B1} represents an integer of 2 or greater, preferably 2 to 8, and more preferably 2 to 6.

The compound represented by formula (C-1) will be described below.

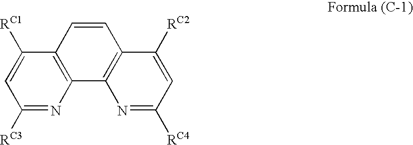

In formula (C-1), R^{C1}, R^{C2}, R^{C3}, and R^{C4} each independently represent a hydrogen atom or a substituent.

Examples of the substituents represented by R^{C1}, R^{C2}, R^{C3}, and R^{C4} include alkyl groups (preferably, those having 1 to 30 carbon atoms, more preferably having 1 to 20 carbon atoms, and particularly preferably having 1 to 10 carbon atoms, such as methyl, ethyl, iso-propyl, tert-butyl, n-octyl, n-decyl, n-hexadecyl, cyclopropyl, cyclopentyl, and cyclohexyl), alkenyl groups (preferably, those having 2 to 30 carbon atoms, more preferably 2 to 20 carbon atoms, and particularly preferably 2 to 10 carbon atoms, such as vinyl, allyl, 2-butenyl, and 3-pentenyl), alkynyl groups (preferably, those having 2 to 30 carbon atoms, more preferably having 2 to 20 carbon atoms, and particularly preferably having 2 to 10 carbon atoms, such as propargyl and 3-pentynyl), aryl groups (preferably, those having 6 to 30 carbon atoms, more preferably 6 to 20 carbon atoms, and particularly preferably 6 to 12 carbon atoms, such as phenyl, p-methylphenyl, naphthyl, and anthranyl), amino groups (preferably, those having 0 to 30 carbon atoms, more preferably 0 to 20 carbon atoms, and particularly preferably 0 to 10 carbon atoms, such as amino, methylamino, dimethylamino, diethylamino, dibenzylamino, diphenylamino, and ditolylamino), alkoxy groups (preferably, those having 1 to 30 carbon atoms, more preferably having 1 to 20 carbon atoms, and particularly preferably having 1 to 10 carbon atoms, such as methoxy, ethoxy, butoxy, and 2-ethylhexyloxy),

aryloxy groups (preferably, those having 6 to 30 carbon atoms, more preferably having 6 to 20 carbon atoms, and particularly preferably having 6 to 12 carbon atoms, such as phenyloxy, 1-naphthyloxy, and 2-naphthyloxy), heterocyclic oxy groups (preferably, those having 1 to 30 carbon atoms, more preferably 1 to 20 carbon atoms, and particularly preferably 1 to 12 carbon atoms, such as pyridyloxy, pyrazyloxy, pyrimidyloxy, and quinolyloxy), acyl groups (preferably, those having 1 to 30 carbon atoms, more preferably having 1 to 20 carbon atoms, and particularly preferably having 1 to 12 carbon atoms, such as acetyl, benzoyl, formyl, and pivaloyl),

alkoxycarbonyl groups (preferably, those having 2 to 30 carbon atoms, more preferably 2 to 20 carbon atoms, and particularly preferably 2 to 12 carbon atoms, such as methoxycarbonyl and ethoxycarbonyl), aryloxycarbonyl groups (preferably, those having 7 to 30 carbon atoms, more preferably having 7 to 20 carbon atoms, and particularly preferably having 7 to 12 carbon atoms, such as phenyloxycarbonyl), acyloxy groups (preferably, those having 2 to 30 carbon atoms, more preferably having 2 to 20 carbon atoms, and particularly preferably having 2 to 10 carbon atoms, such as acetoxy and benzoyloxy), acylamino groups (preferably, those having 2 to 30 carbon atoms, more preferably 2 to 20 carbon atoms, and particularly preferably 2 to 10 carbon atoms, such as acetylamino and benzoylamino), alkoxycarbonylamino groups (preferably, those having 2 to 30 carbon atoms, more preferably 2 to 20 carbon atoms, and particularly preferably 2 to 12 carbon atoms, such as methoxycarbonylamino), aryloxycarbonylamino groups (preferably, those having 7 to 30 carbon atoms, more preferably having 7 to 20 carbon atoms, and particularly preferably having 7 to 12 carbon atoms, such as phenyloxycarbonylamino), sulfonylamino groups (preferably, those having 1 to 30 carbon atoms, more preferably having 1 to 20 carbon atoms, and paticularly preferably having 1 to 12 carbon atoms, such as methanesulfonylamino, benzene sulfonylamino), sulfamoyl groups (preferably, those having 0 to 30 carbon atoms, more preferably 0 to 20 carbon atoms, and particularly preferably 1 to 12 carbon atoms, such as sulfamoyl, methylsulfamoyl, dimethylsulfamoyl, and phenylsulfamoyl), carbamoyl groups (preferably, those having 1 to 30 carbon atoms, more preferably 1 to 20 carbon atoms, and particularly preferably 1 to 12 carbon atoms, such as carbamoyl, methylcarbamoyl, diethylcarbamoyl, and phenylcarbamoyl), alkylthio groups (preferably, those having 1 to 30 carbon atoms, more preferably having 1 to 20 carbon atoms, and particularly preferably having 1 to 12 carbon atoms, such as methylthio and ethylthio), arylthio groups (preferably, those having 6 to 30 carbon atoms, more preferably having 6 to 20 carbon atoms, and particularly preferably having 6 to 12 carbon atoms, such as phenylthio), heterocyclic ring thio group (preferably, those having 1 to 30 carbon atoms, more preferably having 1 to 20 carbon atoms, and particularly preferably having 1 to 12 carbon atoms, such as pyridylthio, 2-benzimidazolylthio, 2-benzoxazolylthio, and 2-benzothiazolylthio),

sulfonyl groups (preferably, those having 1 to 30 carbon atoms, more preferably 1 to 20 carbon atoms, and particularly preferably 1 to 12 carbon atoms, such as mesyl and tosyl), sulfinyl groups (preferably, those having 1 to 30 carbon atoms, more preferably having 1 to 20 carbon atoms, and particularly preferably having 1 to 12 carbon atoms, such as methanesulfinyl and benzenesulfinyl), ureido groups (preferably, those having 1 to 30 carbon atoms, more preferably 1 to 20 carbon atoms, and particularly preferably 1 to 12 carbon atoms, such as ureido, methylureido, and phenylureido), phosphoric amido groups (preferably, those having 1 to 30 carbon atoms, more preferably 1 to 20 carbon atoms, and particularly preferably 1 to 12 carbon atoms, such as diethylphosphoric amido, and phenylphosphoric amido), a hydroxy group, a mercapto group, halogen atoms (e.g., fluorine, chlorine, bromine, and iodine), a cyano group, a sulfo group, a carboxyl group, a nitro group, hydroxamic acid groups, sulfino groups, hydrazino groups, imino groups, heterocyclic ring groups (preferably, those having 1 to 30 carbon atoms, more preferably having 1 to 12 carbon atoms in which heteroatoms may be selected from nitrogen, oxygen, and sulfur atoms, such as imidazolyl, pyridyl, quinolyl, furyl, thienyl, piperidyl, morpholino, benzoxazolyl, benzimidazolyl, benzothiazolyl, carbazolyl, and azepinyl), silyl groups (preferably, those having 3 to 40 carbon atoms, more preferably having 3 to 30 carbon atoms, and particularly preferably having 3 to 24 carbon atoms, such as trimethylsilyl and triphenylsilyl), and silyloxy groups (preferably, those having 3 to 40 carbon atoms, more preferably having 3 to 30 carbon atoms, and particularly preferably having 3 to 24 carbon atoms, such as trimethylsilyloxy and triphenylsilyloxy). These substituents may themselves be substituted. The substituent is preferably an alkyl, aryl, heterocyclic, or a halogen atom, or a silyl group, more preferably an alkyl, aryl, or heterocyclic group, or a halogen atom, and more preferably an alkyl, aryl, or aromatic heterocyclic group, or a fluorine atom.

Typical examples of the compound represented by formula (C-1) include the following compounds.

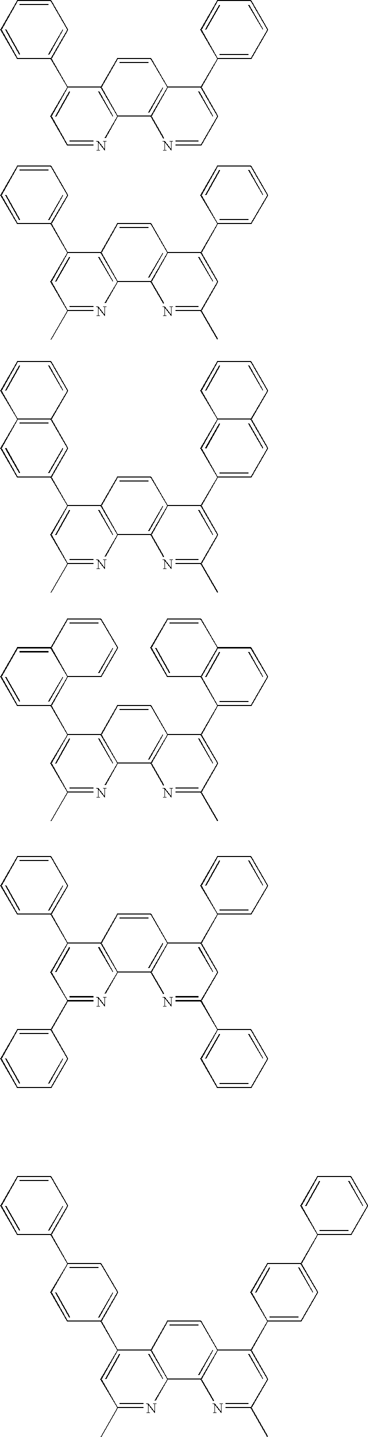

The content of each of the plural host compounds according to the invention is not particularly limited, but is preferably 5 mass % to 95 mass %, more preferably, 10 mass % to 90 mass %, with respect to the total mass of the compounds in the luminescent layer.

-Luminescent Dopant-

The luminescent dopant used in the invention may be a phosphorescent luminescent material or a fluorescent luminescent material, preferably a phosphorescent luminescent material from the viewpoint of luminous efficiency.

The luminescent dopant according to the invention is preferably a dopant satisfying the above-described relationship (1). The luminescent dopant is more preferably satisfies also the relationships (2) with the host compounds: 1.2 eV>ΔIp>0.2 eV, and/or 1.2 eV>ΔEa>0.2 eV from the viewpoint of operational durability.

-Phosphorescent Dopant-

Examples of the phosphorescent dopant in general include complexes containing a transition metal atom or a lanthanoid atom.

The transition metal atom is not particularly limited but preferred examples thereof include ruthenium, rhodium, palladium, tungsten, rhenium, osmium, iridium and platinum. Among these, rhenium, iridium and platinum are more preferred.

Examples of the lanthanoid atom include lanthanum, cerium, praseodymium, neodymium, samarium, europium, gadolinium, terbium, dysprosium, holmium, erbium, thulium, ytterbium and lutecium. Among these lanthanoid atoms, neodymium, europium and gadolinium are preferred.

Examples of the ligand of the complex include ligands described in G Wilkinson et al., Comprehensive Coordination Chemistry, Pergamon Press (1987), H. Yersin, Photochemistry and Photophysics of Coordination Compounds, Springer-Verlag (1987), and Akio Yamamoto, Yuki Kinzoku Kagaku-Kiso to Oyo-(Organic Metal Chemistry-Basics and Applications-), Shokabo (1982), the disclosures of which are incorporated by reference herein.

Specifically, the ligand is preferably a halogen ligand (preferably chlorine ligand), a nitrogen-containing heterocyclic ligand (e.g., phenylpyridine, benzoquinoline, quinolinol, bipyridyl, phenanthroline), a diketone ligand (e.g., acetylacetone), a carboxylic acid ligand (e.g., acetic acid ligand), a carbon monoxide ligand, an isonitrile ligand or a cyano ligand, more preferably a nitrogen-containing heterocyclic ligand.

The complex may contain one transition metal atom in the compound or may be a so-called binuclear complex having two or more transition metal atoms. Also, different metal atoms may be contained at the same time.

Of these phosphorescent dopants, specific examples of the luminescent dopant satisfying the relationships of (1) above include phosphorescent compounds described in U.S. Pat. No. 6,303,238B1, U.S. Pat. No. 6,097,147, WO 00/57676, WO 00/70655, WO 01/08230, WO 01/39234A2, WO 01/41512A1, WO 02/02714A2, WO 02/15645A1, WO 02/44189A1, JP-A Nos. 2001-247859, 2002-302671, 2002-117978, 2001-248165, 2002-235076, 2003-123982, 2002-170684, EP 1211257, JP-A Nos. 2002-226495, 2002-234894, 2001-247859, 2001-298470, 2002-173674, 2002-203678, and 2002-203679, the disclosures of which are incorporated by reference herein. Among these, examples of luminescent dopants satisfying the more preferred relationships of (2) include Ir complexes, Pt complexes, Cu complexes, Re complexes, W complexes, Rh complexes, Ru complexes, Pd complexes, Os complexes, Eu complexes, Tb complexes, Gd complexes, Dy complexes and Ce complexes. In particular, Ir complexes, Pt complexes and Re complexes are preferred, and Ir complexes, Pt complexes and Re complexes each containing at least one coordination mode of metal-carbon bond, metal-nitrogen bond, metal-oxygen bond and metal-sulfur bond are more preferred.

-Fluorescent Dopant-

Examples of the fluorescent dopant in general include benzoxazole, benzimidazole, benzothiazole, styrylbenzene, polyphenyl, diphenylbutadiene, tetraphenylbutadiene, naphthalimide, coumarin, pyran, perynone, oxadiazole, aldazine, pyralidine, cyclopentadiene, bisstyrylanthracene, quinacridone, pyrrolopyridine, thiadiazolopyridine, cyclopentadiene, styrylamine, aromatic dimethylidene compounds, condensed polycyclic aromatic compounds (e.g., anthracene, phenanthroline, pyrene, perylene, rubrene, pentacene), various metal complexes as represented by metal complexes of 8-quinolinol, pyrromethene complexes and rare earth complexes, polymer compounds such as polythiophene, polyphenylene and polyphenylene vinylene, organic silane, and derivatives thereof.

Among these compounds, specific examples of the luminescent dopant satisfying the relationships of (1) include the following compounds.

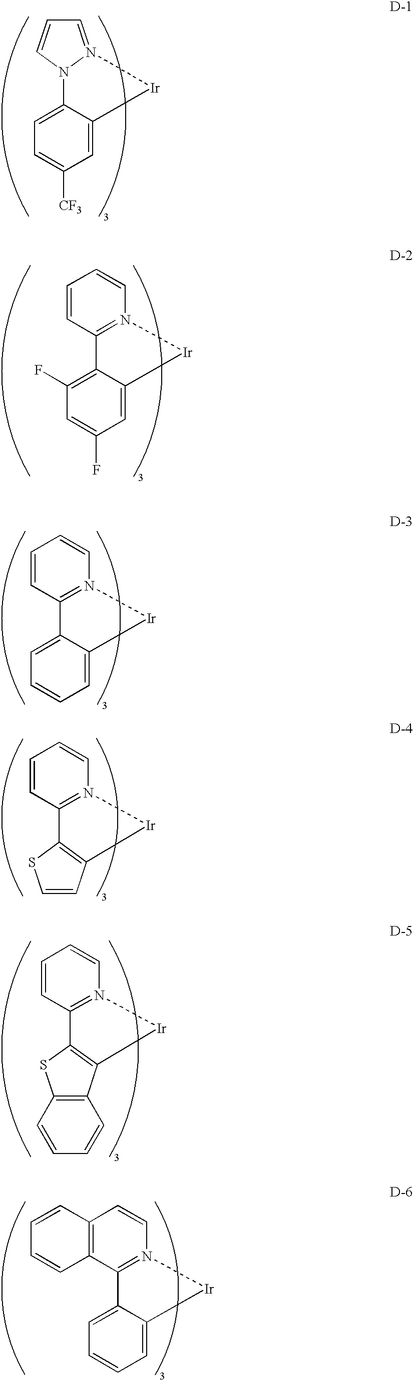

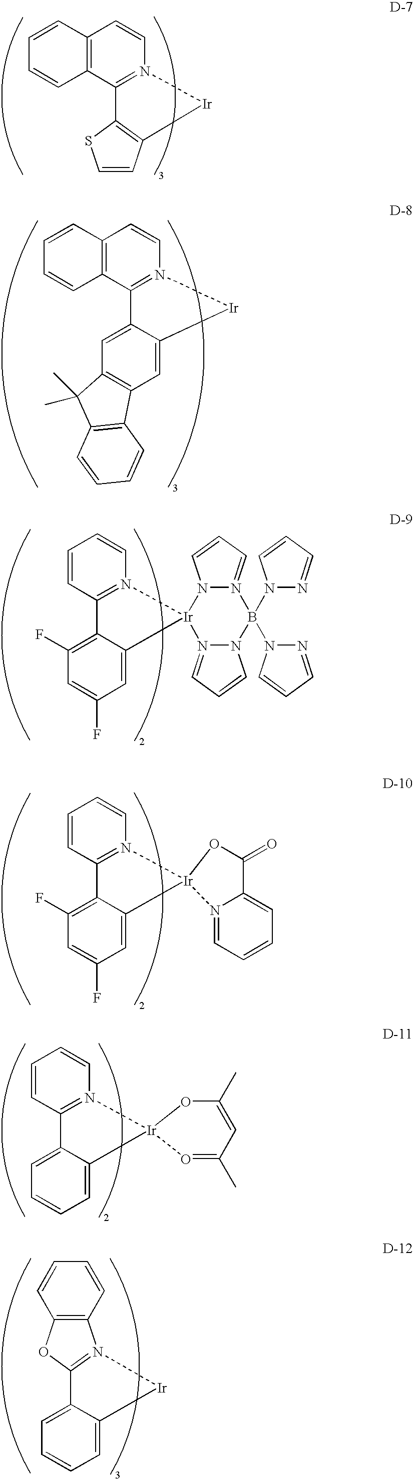

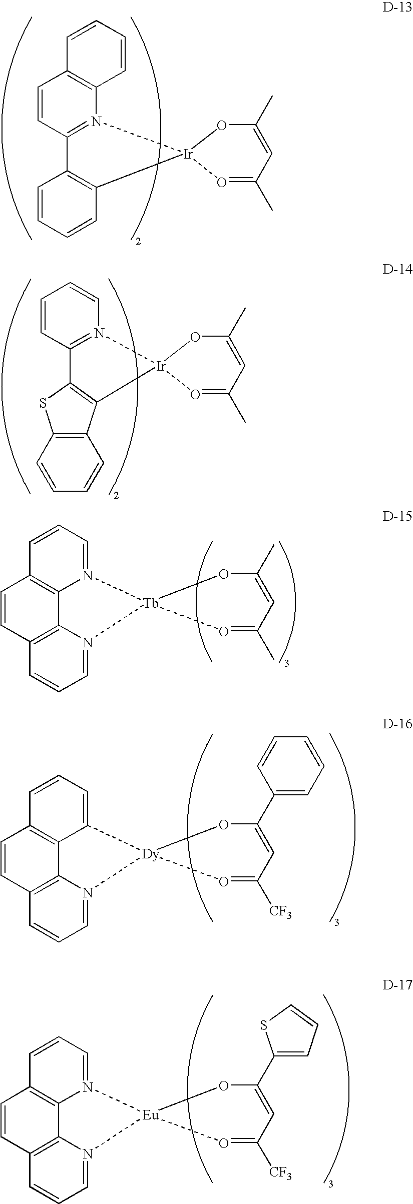

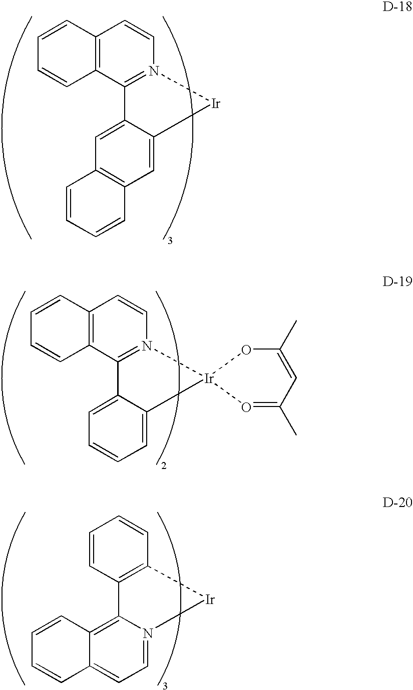

Among these compounds, examples of luminescent dopants satisfying the more preferred relationships of (2) are D-2, D-3, D-4, D-5, D-6, D-7, D-8, D-9, D-10, D-11, D-12, D-13, D-14, and D-20.

The luminescent dopant may be contained in the luminescent layer generally in an amount of 0.1 to 20 mass % based on the mass of all the compounds constituting the luminescent layer, and in view of durability and light emission efficiency, the luminescent dopant is preferably contained in an amount of 1 to 15 mass %, and more preferably 2 to 12 mass %.

The thickness of the luminescent layer is not particularly limited. Usually, the thickness is preferably from 1 nm to 500 nm, and in view of light emission efficiency, more preferably from 5 nm to 200 nm, and still more preferably from 10 to 100 nm.

In the invention, the method of forming the organic compound layers including the luminescent layer is not particularly limited. Examples thereof include a resistance heating deposition method, an electron beam method, a sputtering method, a molecule lamination method, a coating method (spray coating method, dip coating method, dipping method, roll coating method, gravure coating method, reverse coating method, roll brush method, air knife coating method, curtain coating method, spin coating method, flow coating method, bar coating method, micro-gravure coating method, air doctor coating method, blade coating method, squeeze coating method, transfer roll coating method, kiss coating method, cast coating method, extrusion coating method, wire bar coating method, screen coating method, etc.), an ink-jet method, a printing method, and a transfer method, among which the resistance heating deposition method, coating method and transfer method are preferable in consideration of the characteristics of the device and productivity.

The method for forming the luminescent layer including the luminescent dopant and plural host compounds is not particularly limited, and may be a method in which the respective compounds are supplied from respectively different sources followed by mixing of the compounds on the substrate, or a method in which the compounds are supplied onto the substrate in the form of a mixture. For example, in a resistance heating method, the compounds supplied from different deposition sources may be co-deposited, or a mixture of the compounds may be deposited.

There is a case where host compounds co-deposited from different deposition sources do not show interaction (increase in wavelength) while deposition using a mixture of the same host compounds can achieve the interaction (increase in wavelength). From the viewpoint, a method of depositing a mixture of plural host compounds is favorable to the achievement of the interaction (increase in wavelength) according to the invention.

Regarding the deposition of the luminescent dopant, a mixture of the luminescent dopant and one or more of the host compounds may be deposited, or the luminescent dopant may be co-deposited with the host dopants by providing a separate deposition source.

Further, the deposition speed, the ratio between the deposition speeds at co-deposition, the mixing ratio, and the like can be selected appropriately.

The carrier mobility in the luminescent layer may be generally from 10⁻⁷ to 10⁻¹ cm²/V/s, and in view of light emission efficiency, preferably from 10⁻⁵ to 10⁻¹ m²/Vs, more preferably from 10⁻⁴ to 10⁻¹ cm²/Vs, and still more preferably from 10⁻³ to 10⁻¹ cm²/Vs.

In view of driving durability, the carrier mobility in the luminescent layer is preferably smaller than the carrier mobility in the carrier transporting layer, which is described below.

As for the carrier mobility, a value obtained by the measurement according to the TOF method (time-of-flight method, which is incorporated herein by reference) is used as the carrier mobility. The TOF method is described in “Hikari Denshi Kinou Yukizairyo Handbook (Photo/Electronic Functional Organic Material Handbook)” edited by Kazuyuki Horie, published by Asakura Shoten (1995), page 287, the disclosure of which is incorporated by reference herein.

(Hole Injecting Layer and Hole Transporting Layer)

The hole injecting layer and the hole transporting layer each have the function of receiving a hole from an anode or an anode side and of transporting the hole to the cathode side.

The hole injecting layer and the hole transporting layer each preferably include, for example, a carbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted derivative, a styrylanthracene derivative, a fluorenone derivative, a hydrazone derivative, a stilbene derivative, a silazane derivative, an aromatic tertiary amino compound, a styrylamine compound, an aromatic dimethylidyne-based compound, a porphiryn-based compound, an organic silane derivative, carbon, or the like.

The thickness of a hole injecting layer or a hole transporting layer is not particularly limited, but is preferably from 1 nm to 5 μm, more preferably from 5 nm to 1 μm, and still more preferably from 10 nm to 500 mm.

A hole injecting layer or a hole transporting layer may be a single layer structure comprising one kind or two or more kinds of the aforementioned materials, or may also be a multilayer structure comprising a plurality of layers of the same composition or different compositions.

When the carrier transporting layer adjacent to the luminescent layer is a hole transporting layer, in view of driving durability, the Ip(HTL) of the hole transporting layer is preferably smaller than the Ip(D) of the dopant contained in the luminescent layer. The Ip(HTL) of the hole transporting layer can be measured by the above-described measurement method for the Ip.

The carrier mobility in the hole transporting layer may be generally from 10⁻⁷ to 10⁻¹ cm²/Vs, and in view of light emission efficiency, preferably from 10⁻⁵ to 10⁻¹ m²/Vs, more preferably from 10⁻⁴ to 10⁻¹ cm²/Vs, and still more preferably from 10⁻³ to 10⁻¹ cm²/Vs.

As for the carrier mobility, a value measured by the same method as the measurement method for the carrier mobility in the luminescent layer is employed.

Also, in view of driving durability, the carrier mobility in the hole transporting layer is preferably larger than the carrier mobility in the luminescent layer.

An electron accepting dopant may be contained in the hole injecting layer and/or the hole transporting layer of the organic EL element of the invention. The electron accepting dopant usable in the hole injecting layer and/or the hole transporting layer may be an inorganic or organic compound as long as the electron accepting dopant has electron accepting property and is capable of oxidizing an organic compound. Examples of inorganic electron accepting dopants include Lewis acid compounds such as ferric chloride, aluminum chloride, gallium chloride, indium chloride, and antimony pentachloride. Examples of organic electron accepting dopants include: a compound having a substituent selected from a nitro group, a halogen, a cyano group, a trifluoromethyl group, and the like; a quinone compound, an acid anhydride-based compound, and fullerene.

Only one electron accepting dopant may be used, or two or more electron accepting dopants may be used. The amount of the electron accepting dopant to be used depends on the kind of the material, and is preferably 0.01% to 50% by mass (more preferably 0.05% to 20% by mass, still more preferably 0.1% to 10% by mass) based on the mass of the hole transporting material.

(Electron Injecting Layer and Electron Transporting Layer)

The electron injecting layer and the electron transporting layer are each a layer having any one function of receiving an electron from the cathode, transporting an electron, or blocking a hole which is injectable from the anode.

Specific examples of the material for the electron injecting layer and the electron transporting layer include pyridine, pyrimidine, triazine, imidazole, triazole, oxazole, oxadiazole, fluorenone, anthraquinodimethane, anthrone, diphenylquinone, thiopyrandioxide, carbodiimide, fluorenylidenemethane, distyrylpyrazine, fluorine-substituted aromatic compounds, anhydrides of aromatic tetracarboxylic acid (examples of aromatic ring thereof include naphthalene and perylene), phthalocyanine, derivatives thereof (which may form a condensed ring with another ring), and various metal complexes as represented by a metal complex of 8-quinolinol derivative, metal phthalocyanine and a metal complex containing a ligand selected from benzoxazole or benzothiazole.

The electron injecting layer and the electron transporting layer are not particularly limited in their thickness but usually, from the standpoint of decreasing the driving voltage, the thickness is preferably from 1 nm to 5 μm, more preferably from 5 nm to 1 μm, and still more preferably from 10 nm to 500 nm.

The electron injecting layer and the electron transporting layer each may have a single-layer structure comprising one kind of or two or more kinds of the above-described materials or may have a multilayer structure comprising a plurality of layers having the same composition or different compositions.

When the carrier transporting layer adjacent to the luminescent layer is an electron transporting layer, in view of driving durability, the Ea(ETL) of the electron transporting layer is preferably larger than the Ea(D) of the dopant contained in the luminescent layer. As for the Ea(ETL), a value measured by the same method as the above-described measurement method for the Ea is employed.

The carrier mobility in the electron transporting layer may be generally from 10⁻⁷ to 10⁻¹ cm²/Vs and in view of light emission efficiency, preferably from 10⁻⁵ to 10⁻¹ m²/Vs, more preferably from 10⁻⁴ to 10⁻¹ cm²/Vs, and still more preferably from 10⁻³ to 10⁻¹ cm²/Vs.

Also, in view of driving durability, the carrier mobility in the electron transporting layer is preferably larger than the carrier mobility in the luminescent layer. The carrier mobility here is measured by the same method as that for the carrier mobility in the hole transporting layer.

With respect to the carrier mobility of the luminescent element of the present invention, in view of driving durability, the carrier mobility among the hole transporting layer, the electron transporting layer and the luminescent layer is preferably (electron transporting layer≧hole transporting layer)>luminescent layer.

(Hole Blocking Layer)

The hole blocking layer is a layer having a function of preventing a hole which is transported from the anode side to the luminescent layer, from passing through to the cathode side. In the present invention, the hole blocking layer can be provided as an organic compound layer adjacent to the luminescent layer on the cathode side.

The hole blocking layer is not particularly limited. Specifically, the hole blocking layer may comprise an aluminum complex (e.g., BAlq₂), a triazole derivative, a pyrazabole derivative or the like.

In order to decrease the drive voltage, the thickness of the hole blocking layer in general is preferably from 50 nm or less, more preferably from 1 to 50 nm, and still more preferably from 5 to 40 mm.

An electron donating dopant may be contained in one or more layers selected from the hole blocking layer, electron injecting layer, and electron transporting layer of the organic EL element of the invention. The electron donating dopant usable in the hole blocking layer, electron injecting layer, and electron transporting layer has electron donating property and is capable of reducing an organic compound. Examples thereof include alkali metals such as Li, alkaline earth metals such as Mg, transitional metals including rare earth metals, and reducing organic compounds. Preferable metals are metals having a work function of 4.2 eV or less whose examples include Li, Na, K, Be, Mg, Ca, Sr, Ba, Y, Cs, La, Sm, Gd, and Yb. Preferable organic compounds are, for example, nitrogen-containing compounds, sulfur-containing compounds, and phosphorus-containing compounds.

Only one electron donating dopant may be used, or two or more electron donating dopants may be used. The amount of the electron donating dopant to be used depends on the kind of the material, and is preferably 0.1% to 99% by mass (more preferably 1.0% to 80% by mass, still more preferably 2.0% to 70% by mass) based on the mass of the eletron transporting material.

(Anode)

The anode may usually serve as an electrode that supplies holes to the organic compound layer. The shape, structure, size and the like of the anode are not particularly limited and can be selected as appropriate from well known electrodes depending on the applications and purposes of a luminescent element. As mentioned supra, the anode is usually formed as a transparent anode.

Examples of suitable materials for the anode include metals, alloys, metal oxides, electric conductive organic compounds and mixtures thereof, which preferably have a work function of 4.0 eV or more. Specific examples the material of the anode include electric conductive metal oxides such as tin oxides doped with antimony or fluorine (ATO, FTO), tin oxide, zinc oxide, indium oxide, indium tin oxide (ITO), and indium zinc oxide (IZO); metals such as gold, silver, chromium, and nickel; mixtures or laminates of these metals and electric conductive metal oxides; electric conductive inorganic substances such as copper iodide and copper sulfate; electric conductive organic materials such as polyaniline, polythiophene, and polypyrrole; laminates and the like of these and ITO. Among them, the material of the anode is preferably an electric conductive metal oxide, and more preferably ITO from the viewpoint of productivity, high electric conductivity, transparency and the like.

An anode can be formed on the above-described substrate in accordance with a method selected, as appropriate in consideration of its suitability to the materials constituting the above-described anode, from wet methods such as the printing method and the coating method, physical methods such as the vacuum deposition method, the sputtering method and the ion plating method, chemical methods such as CVD and the plasma CVD method, and the like. For instance, when ITO is selected as the material of the anode, the formation of the anode can be carried out according to the direct current or high-frequency sputtering method, the vacuum deposition method, the ion plating method or the like.

In the organic electroluminescent element of the invention, the position of the anode to be formed is not particularly limited and can be selected as necessary depending on the applications or purposes of the luminescent element. The anode may be formed on the entire surface of one surface of the substrate, or may be formed on a portion thereof.

The patterning for forming the anode may be carried out by chemical etching such as photolithography, or may also be carried out by physical etching such as by means of a laser, or may also be carried out by vacuum deposition or sputtering after placing a mask, or may also be carried out by the lift-off method or the printing method.

The thickness of the anode can be selected, as appropriate, depending on the material constituting the above-described anode, thus cannot be specified unconditionally. The thickness of the anode may be usually from 10 nm to 50 μm, and is preferably from 50 nm to 20 μm.

The resistance value of the anode is preferably 10³ Ω/sq or less, and more preferably 10² Ω/sq or less. When the anode is a transparent anode, the anode may be colorless transparent or may also be colored transparent. For the extraction of light emission from the anode side, the transmittance is preferably 60% or more, and more preferably 70% or more.

Additionally, transparent anodes which can be applied to the present invention are described in detail in “Tohmeidodenmaku No Shintenkai (Developments of Transparent Conductive Films)” edited by Yutaka Sawada, published by CMC (1999), the disclosure of which is incorporated by reference herein. When a plastic substrate of low heat resistance is used, ITO or IZO is employed, and a transparent anode that is formed into a film at a low temperature of 150° C. or less is preferable.

(Cathode)

The cathode may usually serve as an electrode that injects an electron to an organic compound layer. The shape, structure, size and the like are not particularly limited and can be selected as appropriate from well known electrodes depending on the applications and purposes of a luminescent element.

Examples of the material of the cathode include metals, alloys, metal oxides, electric conductive compounds and mixtures thereof. The cathode material preferably has a work function of 4.5 eV or less. Specific examples include alkali metals (e.g., Li, Na, K, Cs and the like), alkali earth metals (e.g., Mg, Ca, and the like), gold, silver, lead, aluminum, sodium-potassium alloy, lithium-aluminum alloy, magnesium-silver alloy, indium, rare earth metals such as ytterbium, and the like. Only one cathode material may be used, or two or more cathode materials may be used in combination from the standpoint of balance between stability and electron injection properties.

Among them, preferable examples of the material of the cathode include alkali metals and alkali earth metals in terms of electron injection properties and include materials primarily made of aluminum in terms of excellent shelf life.

A material primarily made of aluminum as used herein means aluminum alone, or an alloy of aluminum and a 0.01 to 10% by mass of alkali metal or alkali earth metal or a mixture thereof (e.g., lithium-aluminum alloy, magnesium-aluminum alloy, and the like).

In addition, materials of the cathode are described in JP-A Nos. 2-15595 and 5-121172, the disclosures of which are incorporated by reference herein, and the materials described in these gazettes can also be applied to the invention.

Methods of forming the cathode are not particularly limited and can be carried out in accordance with well known methods. For instance, a cathode can be formed by a method appropriately selected from wet methods such as the printing method and the coating method; physical methods such as the vacuum deposition method, the sputtering method and the ion plating method; chemical methods such as CVD and the plasma CVD method; and the like, in consideration of the suitability for the materials constituting the above-described cathode,. For example, when metals and the like are selected as materials of the cathode, the cathode can be formed by the sputtering method or the like using one cathode material or two or more cathode materials at the same time or one by one.

The patterning for forming the cathode may be carried out by chemical etching such as photolithography, or may also be carried out by physical etching such as by means of a laser, or may also be carried out by vacuum deposition or sputtering after placing a mask, or may also be carried out by the lift-off method or the printing method.

In the invention, the position of the cathode to be formed is not particularly limited, and the cathode may be formed on the entire organic compound layer, or may be formed on a portion thereof.

Also, a dielectric layer with a thickness of 0.1 nm to 5 nm made of a fluoride or an oxide of an alkali metal or alkali earth metal, or the like, may be inserted between the cathode and the organic compound layer. This dielectric layer can be considered to be a kind of electron injecting layer. The dielectric layer can be formed by, for example, the vacuum deposition method, the sputtering method, the ion plating method or the like.

The thickness of the cathode can be appropriately selected depending on the material constituting the cathode, and thus cannot be specified unconditionally. The thickness of the cathode may be usually from 10 nm to 5 μm, and is preferably from 50 nm to 1 μm.

The cathode may be transparent or may be opaque. A transparent cathode can be formed by a process comprising forming a thin film of the material constituting the cathode having a thickness of 1 to 10 nm, and then laminating thereon a transparent electric-conductive material of ITO, IZO, or the like.

(Substrate)

In the invention a substrate can be used. The substrate to be used in the invention is preferably a substrate that does not scatter or attenuate light emitted from an organic compound layer. Specific examples of the substrate include: inorganic materials such as Yttria-stabilized Zirconia (YSZ) and glass; polyesters such as polyethylene terephthalate, polybutylene phthalate, and polyethylene naphthalate; and organic materials such as polystyrene, polycarbonate, polyether sulfone, polyallylate, polyimides, polycycloolefins, norbornene resin, and poly(chlorotrifluoroethylene).

When the substrate is made of glass, the glass is preferably no-alkali glass in order to reduce ions deriving from the glass. When the substrate is made of soda lime glass, the substrate is preferably coated with a barrier coating such as silica. When an organic material is used, the material is preferably excellent in heat resistance, dimensional stability, solvent resistance, electric insulation and processability.

The shape, structure, size and the like of the substrate are not particularly limited and can be selected appropriately depending on the applications, purposes and the like of a luminescent element. In general, the shape is preferably board-shaped. The structure of the substrate may be a single-layer structure or a laminated structure. The substrate may be formed with a single member or may also be formed with two or more members.

The substrate may be colorless transparent or colored transparent, and is preferably colorless transparent in terms of no scattering or attenuation of the light emitted from the luminescent layer.

A moisture penetration resistance layer (gas barrier layer) can be formed on the front surface or the back surface of the substrate.

Suitable materials for the moisture penetration resistance layer (gas barrier layer) include inorganic substances such as silicon nitrate and silicon oxide. The moisture penetration resistance layer (gas barrier layer) can be formed by, for example, the high-frequency sputtering process or the like.

When a thermoplastic substrate is used, the substrate may be further provided with a hardcoat layer or an undercoat layer as required.

(Protective Layer)

In the invention, the whole organic EL element may be protected by a protective layer.

Any material may be contained in the protective layer insofar as it has the ability to prevent the intrusion of materials (e.g., water, oxygen) which promote the deterioration of the element, into the element.

Specific examples of the material of the protective layer include: metals such as In, Sn, Pb, Au, Cu, Ag, Al, Ti and Ni; metal oxides such as MgO, SiO, SiO₂, Al₂O₃, GeO, NiO, CaO, BaO, Fe₂O₃, Y₂O₃, and TiO₂; metal nitrates such as SiNx and SiNxOy; metal fluorides such as MgF₂, LiF, AlF₃ and CaF₂; polyethylene, polypropylene, polymethylmethacrylate, a polyimide, polyurea, polytetrafluoroethylene, polychlorotrifluoroethylene, polydichlorodifluoroethylene, and a copolymer of chlorotrifluoroethylene with dichlorodifluoroethylene; copolymers obtained by copolymerization of a monomer mixture including tetrafluoroethylene and at least one kind of comonomer; fluorine-containing copolymers having a ring structure on the copolymer backbone thereof; water absorptive materials having a water absorption of 1% or more; moisture-proof materials having a water absorption of 0.1% or less; and the like.

The method of forming the protective layer is not particularly limited. Examples of the method include a vacuum deposition method, a sputtering method, a reactive sputtering method, a MBE (molecular beam epitaxy) method, a cluster ion beam method, an ion plating method, a plasma polymerization method (a high-frequency excited-ion plating method), a plasma CVD method, a laser CVD method, a thermal CVD method, a gas source CVD method, a coating method, a printing method, and a transfer method.

(Sealing)

Furthermore, in the organic electroluminescent element of the invention, the entire element may be sealed with a sealing container.

Also, the space between the sealing container and the luminescent element may be filled with a moisture absorbent or an inert liquid. The moisture absorbent is not particularly limited. Specific examples of the moisture absorbent include barium oxide, sodium oxide, potassium oxide, calcium oxide, sodium sulfate, calcium sulfate, magnesium sulfate, phosphorus pentaoxide, calcium chloride, magnesium chloride, copper chloride, cesium fluoride, niobium fluoride, calcium bromide, vanadium bromide, a molecular sieve, zeolite, magnesium oxide, and the like. An inert liquid is not particularly limited and the examples include paraffins, liquid paraffins, fluorine-based solvents such as perfluoroalkanes, perfluoroamines and perfluoroethers, chlorine-based solvents, and silicone oils.

In the organic electroluminescent element of the present invention, a DC (which, if desired, may contain an AC component) voltage (usually from 2 to 15 V) or a DC current is applied between the anode and the cathode, whereby light emission can be obtained.

In the present invention, the driving durability of the organic electroluminescent element can be measured by the brightness half-life at a specific brightness. For example, a DC voltage is applied to the organic EL element by using the Source Measure Unit Model 2400 manufactured by KEITHLEY, thereby causing light emission. Based on the light emission, a continuous driving test is performed under the condition of the initial brightness of 2,000 cd/m², and the length of time until the brightness decreases to 1,000 cd/m ² is determined as the brightness half-life T(½). This brightness half-life is compared with that of a conventional luminescent element. The numerical value thus obtained is used as the brightness half-life in the present invention.

An important characteristic value of the organic electroluminescent element is its external quantum efficiency. The external quantum efficiency is calculated according to “external quantum efficiency φ=number of photons released from element/number of electrons injected to element”. A larger external quantum efficiency indicates less electric power consumption of the element.

The external quantum efficiency of the organic electroluminescent element is also determined according to “external quantum efficiency φ=internal quantum efficiency×light extraction efficiency”. In the organic EL element utilizing fluorescence emitted from an organic compound, the maximum possible value of the internal quantum efficiency is 25%, and the light extraction efficiency is about 20%; therefore, the maximum possible external quantum efficiency is considered to be about 5%.

The external quantum efficiency of the element is preferably 6% or more, and more preferably 12% or more, from the viewpoint of reduction in the power consumption and elevation of the driving durability.

As the external quantum efficiency, the maximum external quantum efficiency upon driving of the element at 20° C., or the external quantum efficiency at about 100 to about 300 cd/m² (preferably 200 cd/m²) upon driving of the element at 20° C. may be used.

In the present invention, the external quantum efficiency obtained as follows may be used: a constant DC voltage is applied to an EL element by using a Source Measure Unit Model 2400 manufactured by Toyo Corporation to cause light emission; the brightness is measured with a Brightness Meter BM-8 manufactured by Topcon Corporation; and the external quantum efficiency at 200 cd/m² is obtained.

The external quantum efficiency of the luminescent element can also be calculated from the measured values of light emission brightness, light emission spectrum and current density, and the relative luminosity curve. More specifically, the number of electrons inputted can be calculated from the current density value. Then, the light emission brightness can be converted into the number of photons which are emitted as light by integral computation using the light emission spectrum and relative luminosity curve (spectrum), and from the values obtained, the external quantum efficiency (%) can be calculated according to “(number of photons which are emitted as light/number of electrons input into element)×100”.

The driving of an organic electroluminescent element of the invention can utilize methods described in, for example, JP-A Nos. 2-148687, 6-301355, 5-29080, 7-134558, 8-234685 and 8-241047, Japanese Patent No. 2784615, and U.S. Pat. Nos. 5,828,429 and 602,330, the disclosures of which are incorporated by reference herein.

The organic EL element of the invention can be suitably used in the fields of display devices, displays, backlights, electrophotography, light sources for illumination, light sources for recording, light sources for exposure, light sources for reading, signs, sign boards, interiors, optical communications, and the like.

### EXAMPLES

The present invention is described below with reference to Examples, but the present invention is not limited thereto.

### Example 1

On a 2.5 cm-square glass substrate with a thickness of 0.5 mm, an ITO thin film (thickness: 0.2 μm) was formed as a transparent anode by DC magnetron sputtering (conditions: substrate temperature of 100° C., oxygen pressure of 1×10⁻³ Pa) using an ITO target having an In₂O₃ content of 95 mass %. The surface resistance of the ITO thin film was 10 Ω/square.

The substrate having the transparent anode formed thereon was placed in a washing vessel and subjected to IPA washing and then to UV-ozone treatment for 30 minutes. On this transparent anode, copper phthalocyanine was deposited at a rate of 0.5 nm/sec by a vacuum deposition method to provide a hole injecting layer having a thickness of 10 nm.

On this hole injecting layer, 4,4′,4″-tris(2-methylphenylphenylamino)triphenylamine (m-MTDATA) was deposited at a rate of 0.5 nm/sec by a vacuum deposition method to provide a hole transporting layer with a thickness of 40 nm.

In a pot, hole transporting host 1 shown below as the hole transporting host in the luminescent layer and electron transporting host 1 shown below as the electron transporting material in the luminescent layer in a mass ratio of 50:50 were mixed. This mixture and iridium complex 1 (Ir complex 1) shown below as the luminescent material (luminescent dopant) in a ratio of 100:8 (by mass) were co-deposited on the hole transporting layer by a vapor deposition method to form a luminescent layer having a thickness of 30 nm.

On the luminescent layer, BAlq₂ as an electron transporting material of the electron transporting layer was deposited to a thickness of 10 nm at a rate of 0.5 nm/sec by a vacuum deposition method, and Alq₃ as an electron transporting material was deposited thereon at a rate of 0.2 nm/sec by a vacuum deposition method to provide an electron transporting layer having a thickness of 35 nm.

On this electron transporting layer, a patterned mask with a square opening to give a luminescent area of 2 mm×2 mm was placed, and lithium fluoride was deposited by a vacuum deposition method to provide an electron injecting layer having a thickness of 1 nm.

On this electron injecting layer, aluminum was deposited by a vacuum deposition method to provide a cathode having a thickness of 0.15 μm.

An aluminum lead wire was connected to each of the anode and the cathode provided above, whereby a luminescent lamination body was formed.

This luminescent lamination body was placed in a glove box purged with an argon gas, and then sealed by using a stainless-steel sealing can having a desiccant provided therein as well as an ultraviolet-curable adhesive (XNR5516HV, produced by Nagase ChemteX Corporation) to obtain a luminescent element of the present invention.

The operation from the vapor deposition of copper phthalocyanine to the sealing was performed in vacuum or in a nitrogen atmosphere to produce the element without any exposure to air.

The structures of hole transporting host 1, electron transporting host 1, Ir complex 1, BAlq₂, and Alq₃ are shown below. 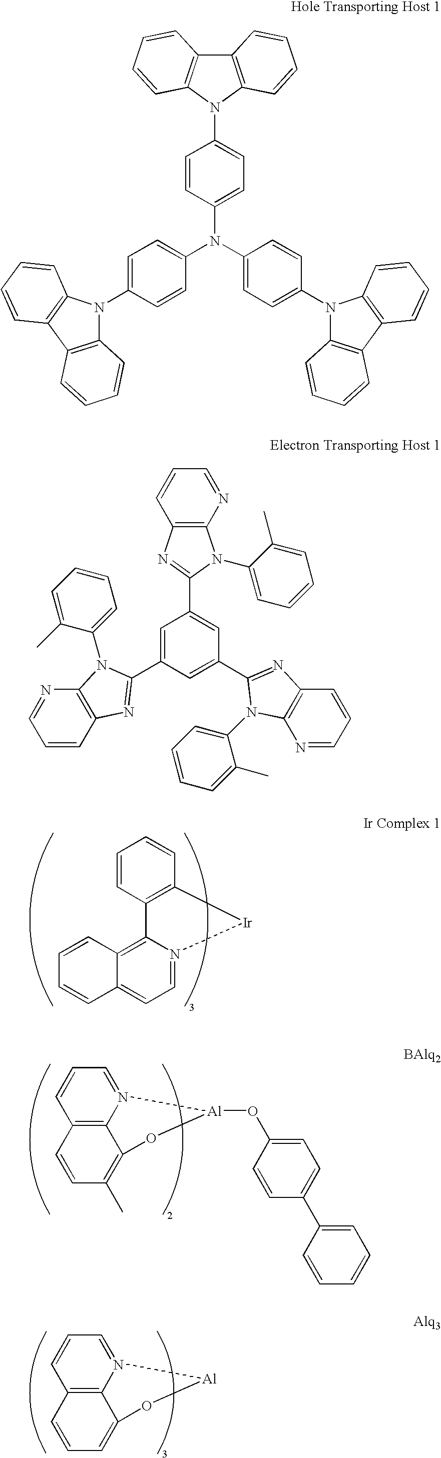
[Evaluation]

The ionization potential (Ip) of the hole transporting material in the luminescent layer and the electron affinity (Ea) of the electron transporting material in the luminescent layer were measured by the following method in terms of a single-layer film (independent layer). The results obtained are shown in Table 1 below. The single layer was formed by depositing only a single compound on a quartz substrate by resistance heating deposition (deposition rate: 0.1 to 1 nm/s) and had a thickness of 50 nm.

-Ionization Potential (Ip)-

The ionization potential (Ip) was measured by an ultraviolet photoelectron analyzer AC-1 (manufactured by Riken Keiki Co., Ltd.).

The measurement condition and analysis method were determined with reference to Chihaya Adachi et al., Yuki Hakumaku Sigoto Kansu Data Shu (Work Function Data of Organic Thin Film), CMC (2004), the disclosure of which is incorporated by reference herein. The measurement was conducted at room temperature and atmospheric pressure.

-Electron Affinity (Ea)-

The electron affinity (Ea) was obtained as follows: calculating the band gap based on the absorption spectrum of the single-layer film and then calculating the electron affinity (Ea) based on the values of the calculated band gap and the above ionization potential (Ip).

-λmax in the Emission Spectra of Hole Transporting Host (HTH) and Electron Transporting Host (ETH)-

λmax in the emission spectrum of each host compound was determined by measuring the single-layer film deposited on the quartz substrate described above, using a fluorescence photometer RF-5300PC (manufactured by Shimadzu Corporation). The measurement was performed at room temperature in the atmosphere. For the measurement, an excitation light that can be absorbed by each of the host compounds was used.

-λmax in the Emission Spectrum of Mixed Host-

The emission spectrum of mixed host was determined by preparing a vapor-deposited film under the same deposition condition as the preparation of the luminescent layer except that the luminescent dopant was not used, and measuring the emission spectrum of the obtained film. The measurement of the emission spectrum was conducted in the same manner as described above.

-External Quantum Efficiency-

Using the luminescent element obtained above, the external quantum efficiency was measured by the following method.

The waveform of the light emission spectrum of the produced luminescent element was measured with a spectrophotometer SR-3 manufactured by Topcon Corporation. Based on the measured data, the wavelength value at the light emission peak was determined. Thereafter, the external quantum efficiency was calculated from the measured waveform of the light emission spectrum and the current and brightness (200 cd/m²) at the measurement, and evaluated according to the following criteria. The results are shown in Table 1 below.

[Evaluation Criteria]

A: 10% or more

B: 6% or more but less than 10%

C: 3% or more but less than 6%

D: less than 3%

-Driving Durability Test-

A DC voltage was applied to the organic EL element by using a Source Measure Unit Model 2400 manufactured by KEITHLEY to cause light emission, the brightness of which was measured with a Brightness Meter BM-8 manufactured by Topcon Corporation. Subsequently, this luminescent element was subjected to a continuous driving test under such a condition to give an initial brightness of 2,000 cd/m², the length of time until the brightness decreased to 1,000 cd/m² was determined as a brightness half-life T(½), and this brightness half-life was evaluated according to the following evaluation criteria.

[Evaluation Criteria]

A: 500 hr or more

B: 250 hr or more and less than 500 hr

C: 100 hr or more and less than 250 hr

D: less than 100 hr

### Comparative Example 1

An element of Comparative Example 1 was prepared in the same manner as in Example 1, except that the hole transporting host 1 and the Ir complex 1 were co-deposited in a ratio of 100/8 (by mass) by vacuum deposition to give a luminescent layer having a thickness of 30 nm.

### Comparative Example 2

An element of Comparative Example 2 was prepared in the same manner as in Example 1 except that the electron transporting host 1 and the Ir complex 1 were co-deposited in a ratio of 100/8 (by mass) by vacuum deposition to give a luminescent layer having a thickness of 30 nm.

### Comparative Example 3

An element of Comparative Example 3 was prepared in the same manner as in Example 1 except that the hole transporting host 1, the electron transporting host 1 and the Ir complex 1 were co-deposited in a ratio of 50/50/8 (by mass) by vacuum deposition from respectively separate deposition sources to give a luminescent layer having a thickness of 30 nm.

### Example 2

An element of Example 2 was prepared in the same manner as in Example 1, except that the Ir complex 1 (luminescent material) and a mixture of the following hole transporting host 2 (hole transporting host in the luminescent layer) and electron transporting host 2 (electron transporting host in the luminescent layer) that was blended in a crucible in a mass ratio of 50:50 were co-deposited by vacuum deposition in a ratio of 8/100 (by mass) to give a luminescent layer having a thickness of 30 nm.

### Example 3

An element of Example 3 was prepared in the same manner as in Example 1, except that the Ir complex 1 (luminescent material) and a mixture of the following hole transporting host 3 (hole transporting host in the luminescent layer) and electron transporting host 3 (electron transporting host in the luminescent layer) that was blended in a crucible in a mass ratio of 50:50 were co-deposited by vacuum deposition at a ratio of 8/100 (by mass) to give a luminescent layer having a thickness of 30 nm.

The structures of the hole transporting hosts 2 and 3 and of the electron transporting hosts 2 and 3 used in Examples 2 and 3 are shown below.

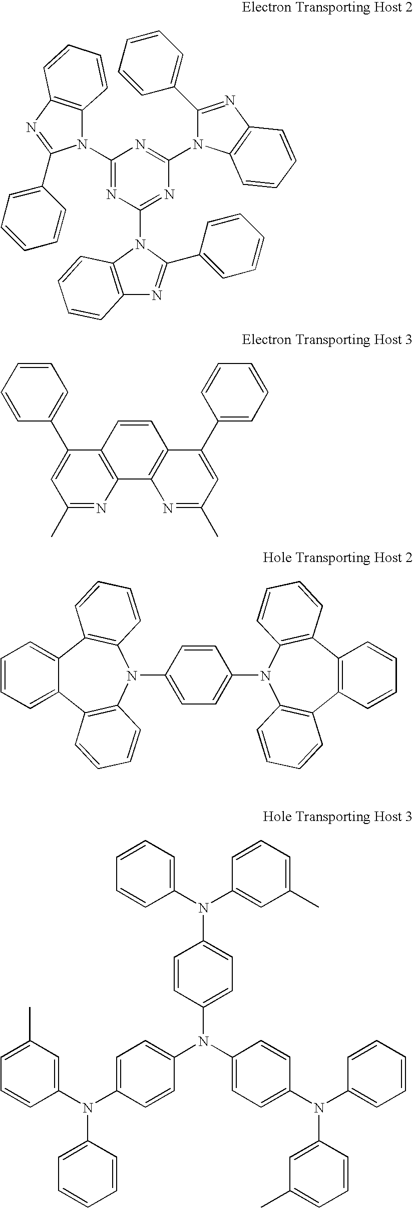

TABLE 1

| | | | | Comparative | Comparative | Comparative |
|---|---|---|---|---|---|---|
| | Example 1 | Example 2 | Example 3 | Example 1 | Example 2 | Example 3 |
| Luminescent dopant | Ir complex 1 (red) | Ir complex 1 (red) | Ir complex 1 (red) | Ir complex | Ir complex 1 (red) | Ir complex 1 (red) |
| | | | | 1 (red) | | |
| Hole transporting host | Hole transporting | Hole transporting | Hole transporting | Hole | — | Hole transporting |
| (HTH) | host 1 | host 2 | host 3 | transporting | | host 1 |
| | | | | host 1 | | |
| Electron transporting | Electron | Electron | Electron | — | Electron | Electron |
| host (ETH) | transporting host 1 | transporting host 2 | transporting host 3 | | transporting host 1 | transporting host 1 |
| Film forming condition | Deposition from a | Deposition from a | Deposition from a | Deposition | Deposition of one | Co-deposition from |
| for host compound | mixture of the two | mixture of the two | mixture of the two | of one host | host compound | separate deposition |
| | host compounds | host compounds as | host compounds as | compound | | sources for the two |
| | as the deposition | the deposition | the deposition | | | host compounds |
| | source | source | source | | | |
| Ip of HTH | 5.7 | 5.4 | 5.1 | 5.7 | — | 5.7 |
| Ea of ETH | 3.5 | 3.5 | 3.0 | — | 3.5 | 3.5 |
| λmax in emission | 408 nm | 508 nm | 427 nm | 408 nm | — | 408 nm |
| spectrum of HTH | | | | | | |
| λmax in emission | 380 nm | 426 nm | 390 nm | — | 380 nm | 380 nm |
| spectrum of ETH | | | | | | |
| λmax in emission | 450 nm | 540 nm | 520 nm | — | — | 410 nm |
| spectrum of mixed host | | | | | | |
| External quantum | B | A | A | C | D | C |
| efficiency | | | | | | |
| Operational durability | A | B | B | B | D | A |

As is apparent from Table 1, in each of Examples 1 to 3, λmax in the emission spectrum of the single-layer film containing only the plural host compounds (mixed host) prepared under the same condition as the preparation of the luminescent layer, was longer by at least 15 nm than the main peak of the emission spectrum of each of the plural host compounds; the results indicate that an interacting complex was formed among the host compounds.

Comparison between the double host (DH) luminescent element of Example 1 containing the interacting complex and the single host (SH) luminescent elements of Comparative Example 1 and 2 reveals that the luminescent element of Example was superior both in emission characteristics (external quantum efficiency) and operational durability.

In Example 1 and Comparative Example 3, the same host material was used in different vapor-deposition methods. When Example 1 and Comparative Example 3 are compared, interaction was observed in Example 1 while interaction could not be observed in Comparative Example 3. The interaction hardly occurs when Ip of the hole transporting host is more than 5.4 eV. However, the results clarified that the interaction is more likely to occur when the deposition from a mixture of the host compounds is conducted. Further, it was made clear that the interaction achieved a higher external quantum efficiency even when the same combination of host compounds was used.

Based on the comparison of Examples 1 and Examples 2 and 3, it was found that a higher external quantum efficiency could be obtained when the ionization potential Ip of the hole transporting host material is 5.4 eV or less.

The luminescent element according to the present invention can be advantageously applied to the fields of display devices, displays, back lights, electrophotography, illumination light sources, recording light sources, exposure light sources, reading light sources, signs and marks, signboards, interior goods, optical communication, and the like. In addition, the compound used in the invention is applicable also to medical applications, fluorescent brighteners, photographic materials, UV absorption materials, laser colorants, materials for recording media, ink-jet pigments, color-filter dyes, color conversion filters, and the like.

The disclosure of JP-A No. 2005-336344 is incorporated herein by reference.

What is claimed is:

1. An organic electroluminescent element comprising at least one organic compound layer between a pair of electrodes, wherein the at least one organic compound layer includes at least one luminescent layer, the luminescent layer comprises at least one luminescent dopant and plural host compounds, and the main peak in an emission spectrum of a single-layer film comprising only the plural host compounds prepared under the same film-forming conditions under which the luminescent layer is prepared has a wavelength that is at least 15 nm longer than the main peak wavelength of an emission spectrum of each of the plural host compounds.

2. The organic electroluminescent element according to claim 1, wherein at least one of the plural host compounds contained in the luminescent layer is a compound having an electron affinity Ea of 2.8 eV or more.

3. The organic electroluminescent element according to claim 1, wherein at least one of the plural host compounds contained in the luminescent layer is a compound having an ionization potential Ip of 5.4 eV or less.

4. The organic electroluminescent element according to claim 3, wherein at least one of the plural host compounds contained in the luminescent layer is a compound having an electron affinity Ea of 2.8 eV or more.

5. The organic electroluminescent element according to claim 1, wherein the main peak in an emission spectrum of a single-layer film comprising only the plural host compounds prepared under the same film-forming conditions under which the luminescent layer is prepared has a wavelength that is 20 to 120 nm longer than the main peak wavelength of an emission spectrum of each of the plural host compounds.

6. The organic electroluminescent element according to claim 1, wherein the main peak in an emission spectrum of a single-layer film comprising only the plural host compounds prepared under the same film-forming conditions under which the luminescent layer is prepared has a wavelength that is 30 to 100 nm longer than the main peak wavelength of an emission spectrum of each of the plural host compounds.

7. The organic electroluminescent element according to claim 1, wherein at least one of the plural host compounds contained in the luminescent layer is a compound represented by formula (A-1): 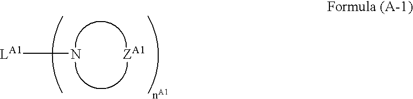
wherein in formula (A-1), L represents a connecting group; Z^{A1} represents an atom group necessary for forming a nitrogen-containing heterocyclic ring; n^{A1} represents an integer of 2 or greater; and the compound represented by formula (A-1) has at least three nitrogen atoms in the molecule.

8. The organic electroluminescent element according to claim 1, wherein at least one of the plural host compounds contained in the luminescent layer is a compound represented by formula (B-1): 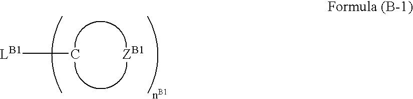
wherein in formula (B-1), L^{B1} represents a connecting group; Z^{B1} represents an atom group necessary for forming an aromatic hydrocarbon ring or an aromatic heterocyclic ring; n^{B1} represents an integer of 2 or greater; and the compound represented by formula (B-1) has at least three nitrogen atoms in the molecule.

9. The organic electroluminescent element according to claim 1, wherein at least one of the plural host compounds contained in the luminescent layer is a compound represented by formula (C-1): 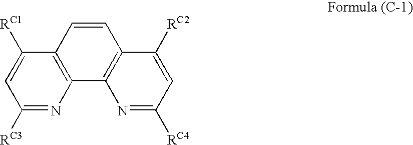
wherein in formula (C-1), R^{C1}, R^{C2}, R^{C3}, and R^{C4} each independently represent a hydrogen atom or a substituent.

10. The organic electroluminescent element according to claim 1, wherein at least one of the plural host compounds contained in the luminescent layer is a compound represented by formula (D-1): 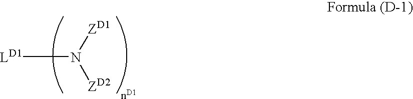
wherein in formula (D-1), L represents a connecting group; Z^{D1} and Z^{D2} each independently represent a monovalent atom group; Z^{D1} and Z^{D2} may be bonded to each other to form a nitrogen-containing heterocyclic ring; n^{D1} represents an integer of 2 or greater; and
the compound represented by formula (D-1) has at least three nitrogen atoms in the molecule.

11. The organic electroluminescent element according to claim 1, wherein at least one of the plural host compounds contained in the luminescent layer is a compound represented by formula (E-1): 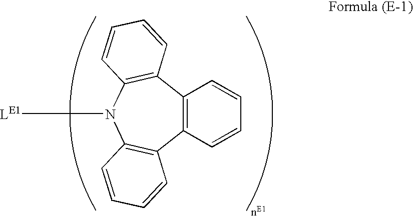
wherein in formula (E-1), L^{E1} represents a connecting group; and n^{E1} represents an integer of 2 or greater.

12. The organic electroluminescent element according to claim 1, wherein the light emitted from the luminescent dopant contained in the luminescent layer is phosphorescent light.

13. The organic electroluminescent element according to claim 1, in which the relationships of ΔIp>0 eV and ΔEa>0 eV are satisfied, wherein Ip(D) represents an ionization potential of the luminescent dopant; Ip(H)min represents the minimum ionization potential among those of the plural host compounds; ΔIp represents Ip(D)−Ip(H)min; Ea(D) represents an electron affinity of the luminescent dopant; Ea(H)max represents the maximum electron affinity among those of the plural host compounds; and ΔEa represents Ea(H)max−Ea(D).

14. The organic electroluminescent element according to claim 1, wherein the luminescent layer is formed by a vapor deposition method in which a mixture of the plural host compounds is used as a deposition source.

15. A method of producing an organic electroluminescent element, the method comprising forming at least one luminescent layer between a pair of electrodes by a vapor deposition method in which at least one luminescent dopant and a mixture of plural host compounds are used as deposition sources, wherein the main peak in an emission spectrum of a single-layer film comprising only the plural host compounds prepared under the same film-forming conditions under which the luminescent layer is prepared has a wavelength that is at least 15 nm longer than the main peak wavelength of an emission spectrum of each of the plural host compounds.
